(19) United States
(12) Patent Application Publication
(10) Pub. No.: US 2024/0194004 A1
(43) Pub. Date: Jun. 13, 2024

(54) PERFORMANCE TESTING FOR MOBILE ROBOT TRAJECTORY PLANNERS

(71) Applicant: Five Al Limited, Cambridge (GB)

(72) Inventors: Iain Whiteside, Edinburgh (GB); Marco Ferri, Cambridge (GB)

(73) Assignee: Five Al Limited, Cambridge (GB)

(21) Appl. No.: 18/287,919

(22) PCT Filed: Apr. 22, 2022
(86) PCT No.: PCT/EP2022/060764

§ 371 Date: Oct. 23, 2023

(30) Foreign Application Priority Data
Apr. 23, 2021 (GB) 2105836.7
Jun. 2, 2021 (GB) 2107876.1
Nov. 2, 2021 (GB) 2115740.9

(51) Int. Cl. G07C 5/06

(52) U.S. Cl. CPC G07C 5/06

(57) ABSTRACT

A computer-implemented method of evaluating the performance of a trajectory planner for a mobile robot in a real or simulated scenario, the method comprising: receiving scenario ground truth of the scenario, the scenario ground truth generated using the trajectory planner to control an ego agent of the scenario responsive to at least one other agent of the scenario, and comprising an ego trace of the ego agent and an agent trace of the other agent; evaluating the ego trace, by a test oracle, in order to assign at least one time series of test results to the ego agent, the time-series of test results pertaining to at least one performance evaluation rule; extracting one or more predetermined blame assessment parameters based on the agent trace; and applying one or more predetermined blame assessment rules to the blame assessment parameters, and thereby determining whether failure on the at least one performance evaluation rule is acceptable.

### TECHNICAL FIELD

The present disclosure pertains to methods for evaluating the performance of trajectory planners in real or simulated scenarios, and computer programs and systems for implementing the same. Such planners are capable of autonomously planning ego trajectories for fully/semi-autonomous vehicles or other forms of mobile robot. Example applications include ADS (Autonomous Driving System) and ADAS (Advanced Driver Assist System) performance testing.

### BACKGROUND

There have been major and rapid developments in the field of autonomous vehicles. An autonomous vehicle (AV) is a vehicle which is equipped with sensors and control systems which enable it to operate without a human controlling its behaviour. An autonomous vehicle is equipped with sensors which enable it to perceive its physical environment, such sensors including for example cameras, radar and lidar. Autonomous vehicles are equipped with suitably programmed computers which are capable of processing data received from the sensors and making safe and predictable decisions based on the context which has been perceived by the sensors. An autonomous vehicle may be fully autonomous (in that it is designed to operate with no human supervision or intervention, at least in certain circumstances) or semi-autonomous. Semi-autonomous systems require varying levels of human oversight and intervention, such systems including Advanced Driver Assist Systems and level three Autonomous Driving Systems. There are different facets to testing the behaviour of the sensors and control systems aboard a particular autonomous vehicle, or a type of autonomous vehicle.

A “level 5” vehicle is one that can operate entirely autonomously in any circumstances, because it is always guaranteed to meet some minimum level of safety. Such a vehicle would not require manual controls (steering wheel, pedals etc.) at all.

By contrast, level 3 and level 4 vehicles can operate fully autonomously but only within certain defined circumstances (e.g. within geofenced areas). A level 3 vehicle must be equipped to autonomously handle any situation that requires an immediate response (such as emergency braking); however, a change in circumstances may trigger a “transition demand”, requiring a driver to take control of the vehicle within some limited timeframe. A level 4 vehicle has similar limitations; however, in the event the driver does not respond within the required timeframe, a level 4 vehicle must also be capable of autonomously implementing a “minimum risk maneuver” (MRM), i.e. some appropriate action(s) to bring the vehicle to safe conditions (e.g. slowing down and parking the vehicle). A level 2 vehicle requires the driver to be ready to intervene at any time, and it is the responsibility of the driver to intervene if the autonomous systems fail to respond properly at any time. With level 2 automation, it is the responsibility of the driver to determine when their intervention is required; for level 3 and level 4, this responsibility shifts to the vehicle's autonomous systems and it is the vehicle that must alert the driver when intervention is required.

Safety is an increasing challenge as the level of autonomy increases and more responsibility shifts from human to machine. In autonomous driving, the importance of guaranteed safety has been recognized. Guaranteed safety does not necessarily imply zero accidents, but rather means guaranteeing that some minimum level of safety is met in defined circumstances. It is generally assumed this minimum level of safety must significantly exceed that of human drivers for autonomous driving to be viable.

According to Shalev-Shwartz et al. “On a Formal Model of Safe and Scalable Self-driving Cars” (2017), arXiv:1708.06374 (the RSS Paper), which is incorporated herein by reference in its entirety, human driving is estimated to cause of the order 10⁻⁶ severe accidents per hour. On the assumption that autonomous driving systems will need to reduce this by at least three order of magnitude, the RSS Paper concludes that a minimum safety level of the order of 10⁻⁹ severe accidents per hour needs to be guaranteed, noting that a pure data-driven approach would therefore require vast quantities of driving data to be collected every time a change is made to the software or hardware of the AV system.

The RSS paper provides a model-based approach to guaranteed safety. A rule-based Responsibility-Sensitive Safety (RSS) model is constructed by formalizing a small number of “common sense” driving rules:
“1. Do not hit someone from behind.
2. Do not cut-in recklessly.
3. Right-of-way is given, not taken.
4. Be careful of areas with limited visibility.
5. If you can avoid an accident without causing another one, you must do it.”

The RSS model is presented as provably safe, in the sense that, if all agents were to adhere to the rules of the RSS model at all times, no accidents would occur. The aim is to reduce, by several orders of magnitude, the amount of driving data that needs to be collected in order to demonstrate the required safety level.

A safety model (such as RSS) can be used as a basis for evaluating the quality of trajectories realized by an ego agent in a real or simulated scenario under the control of an autonomous system (stack). The stack is tested by exposing it to different scenarios, and evaluating the resulting ego trajectories for compliance with rules of the safety model (rules-based testing). A rules-based testing approach can also be applied to other facets of performance, such as comfort or progress towards a defined goal.

### SUMMARY

Identifying “interesting” events is a significant challenge when testing sophisticated robotic systems, such as autonomous vehicles. Nowadays, such systems are capable of performing to an extremely high standard, with few instances of failure. With a rules-based safety model, it is relatively straightforward to isolate instances of failure with respect to the safety model. However, not every instance of failure is necessarily that informative. For example, if a stack is tested in simulation, a failure of a stack on an unrealistic or highly unlikely scenario is generally less informative than a failure on a more realistic or likely scenario.

According to a first aspect herein, a computer-implemented method of evaluating the performance of a trajectory planner for a mobile robot in a real or simulated scenario, the method comprises:
receiving scenario ground truth of the scenario, the scenario ground truth generated using the trajectory planner to control an ego agent of the scenario responsive to at least one other agent of the scenario, and comprising an ego trace of the ego agent and an agent trace of the other agent;
evaluating the ego trace, by a test oracle, in order to assign at least one time series of test results to the ego agent, the time-series of test results pertaining to at least one performance evaluation rules;
extracting one or more predetermined blame assessment parameters based on the agent trace; and
applying one or more predetermined blame assessment rules to the blame assessment parameters, and thereby determining whether failure on the at least one performance evaluation rule is acceptable.

In this manner, rules-based testing is extended to incorporate a concept of blame. The blame assessment rules define what is referred to herein as an “acceptable failure” model for the scenario question. For example, human driving capabilities provide a benchmark for ascribing blame, with the other agent being identified as the cause of the failure event if the circumstances are such that no reasonable human driver could have prevented the failure event.

In embodiments, the method may comprise the step of detecting an action by the other agent of a predetermined type, wherein the blame assessment parameters are extracted based on the detected action.

The blame assessment parameters may comprise a distance between the ego agent and the other agent at a time of the detected action.

The blame assessment parameters may comprise at least one motion parameter of the other agent at a time of the detected action.

The one or more predetermined blame assessment rules may be applied to identify one of the ego agent and the other agent as having caused a failure event in the at least one time series of test results.

The action may occur before the failure event.

The blame assessment parameters may comprise a time interval between the detected action and the failure event.

Rules-based evaluation of complex scenario ground, over many scenarios, requires significant computational resources. Certain embodiments limit the extent to which additional processing is required, by instigating a blame assessment process in response to a failure event and restricting the assessment of the other agent's trace based on the timing of the blame assessment process (e.g. to within some predetermined time window before and/or after the failure event).

The predetermined blame assessment rules may be applied to only a portion of the agent trace within a time period defined by the timing of the failure event.

The one or more predetermined blame assessment parameters may be extracted responsive to the failure event in the at least one time-series of test results based on the agent trace and a timing of the failure event.

Alternatively, the predetermined blame assessment rules may be applied irrespective of whether any failure event occurs in the at least one time series of test results.

The scenario may be assigned a classification label denoting that:
an acceptable failure event occurred in the at least one time-series of test results,
an unacceptable failure event occurred in the at least one time-series of test results,
no failure event occurred in the at least one time-series of test results and such a failure event would not have been acceptable, or
no failure event occurred in the at least one time-series of test results and such a failure event would have been acceptable.

The classification label may be stored in association with a set of scenario parameters parameterizing the scenario.

The method may comprise generating display data for generalizing a visualization of the scenario parameters and the classification label.

The method may comprise the step of generating display data for displaying a rule timeline with a visual indication of whether failure on the at least one performance evaluation rule is acceptable, the rule timeline being a visual representation of the time-series.

The failure result and the causing agent may be visually identified in the rule timeline.

The method may comprise the step of rendering a graphical user interface comprising the rule timeline with the visual indication.

The method may comprise the step of storing the time-series of results in a test database, with an indication of whether failure on the at least one performance evaluation rule is acceptable.

The time-series of results may be stored in the test database with an indication of the causing agent.

According to a second aspect herein, a computer-implemented method of evaluating the performance of a trajectory planner for a mobile robot in a real or simulated scenario, the method comprises:
receiving scenario ground truth of the scenario, the scenario ground truth generated using the trajectory planner to control an ego agent of the scenario responsive to at least one other agent of the scenario, and comprising an ego trace of the ego agent and an agent trace of the other agent;
evaluating the ego trace, by a test oracle, in order to assign at least one time series of test results to the ego agent, the time-series of test results pertaining to at least one performance evaluation rules;
responsive to a failure event in the at least one time-series of test results, extracting one or more predetermined blame assessment parameters based on the agent trace and a timing of the failure event; and
applying one or more predetermined blame assessment rules to the blame assessment parameters, and thereby identifying one of the ego agent and the other agent as having caused the failure event.

In embodiments, the method may comprise the step of detecting an action by the other agent of a predetermined type, the action occurring before the failure event, wherein the blame assessment parameters are extracted based on the detected action.

The blame assessment parameters may comprise a time interval between the detected action and the failure event.

The blame assessment parameters may comprise a distance between the ego agent and the other agent at a time of the detected action.

The blame assessment parameters may comprise at least one motion parameter of the other agent at a time of the detected action.

The method may comprise the step of generating display data for displaying a rule timeline, the rule timeline being a visual representation of the time-series, in which the failure result and the causing agent are visually identified.

The method may comprise the step of rendering a graphical user interface comprising the rule timeline.

The method may comprise the step of storing the time-series of results in a test database, with an indication of the causing agent.

The method may comprise the predetermined blame assessment rules are applied to only a portion of the agent trace within a time period defined by the timing of the failure event. Further aspects provide a computer system comprising one or more computers configured to implement the method of the first or second aspect or any embodiment thereof, and executable program instructions for programming a computer system to implement the same. One or more computer programs may be embodied in transitory or non-transitory media, and configured when executed by one or more computers to implement the method.

### BRIEF DESCRIPTION OF FIGURES

For a better understanding of the present disclosure, and to show how embodiments of the same may be carried into effect, reference is made by way of example only to the following figures in which:

FIG. 1A shows a schematic function block diagram of an autonomous vehicle stack;

FIG. 1B shows a schematic overview of an autonomous vehicle testing paradigm;

FIG. 1C shows a schematic block diagram of a scenario extraction pipeline;

FIG. 2 shows a schematic block diagram of a testing pipeline;

FIG. 2A shows further details of a possible implementation of the testing pipeline;

FIG. 3A shows an example of a rule tree evaluated within a test oracle;

FIG. 3B shows an example output of a node of a rule tree;

FIG. 4A shows an example of a rule tree to be evaluated within a test oracle;

FIG. 4B shows a second example of a rule tree evaluated on a set of scenario ground truth data;

FIG. 4C shows how rules may be selectively applied within a test oracle;

FIG. 5 shows a schematic block diagram of a visualization component for rendering a graphical user interface;

FIGS. 5A, 5B and 5C show different views available within a graphical user interface;

FIG. 6A shows a first instance of a cut-in scenario;

FIG. 6B shows an example oracle output for the first scenario instance;

FIG. 6C shows a second instance of a cut-in scenario;

FIG. 6D shows an example oracle output for the second scenario instance;

FIG. 7 shows a block diagram of an extended test oracle capable of receiving and applying an acceptable failure model;

FIG. 8 shows a flow chart for a blame assessment method; and

FIG. 9 shows an extended graphical user interface rendered in a computer system;

FIGS. 10 and 11 show respective scenario space visualizations, with points corresponding to scenario runs classified according to different failure categories.

### DETAILED DESCRIPTION

The described embodiments provide a testing pipeline to facilitate rules-based testing of mobile robot stacks in real or simulated scenarios. Agent (actor) behaviour in real or simulated scenarios is evaluated by a test oracle based on defined performance evaluation rules. Such rules may evaluate different facets of safety. For example, a safety rule set may be defined to assess the performance of the stack against a particular safety standard, regulation or safety model (such as RSS), or bespoke rule sets may be defined for testing any aspect of performance. The testing pipeline is not limited in its application to safety, and can be used to test any aspects of performance, such as comfort or progress towards some defined goal. A rule editor allows performance evaluation rules to be defined or modified and passed to the test oracle.

A “full” stack typically involves everything from processing and interpretation of low-level sensor data (perception), feeding into primary higher-level functions such as prediction and planning, as well as control logic to generate suitable control signals to implement planning-level decisions (e.g. to control braking, steering, acceleration etc.). For autonomous vehicles, level 3 stacks include some logic to implement transition demands and level 4 stacks additionally include some logic for implementing minimum risk maneuvers. The stack may also implement secondary control functions e.g. of signalling, headlights, windscreen wipers etc.

The term “stack” can also refer to individual sub-systems (sub-stacks) of the full stack, such as perception, prediction, planning or control stacks, which may be tested individually or in any desired combination. A stack can refer purely to software, i.e. one or more computer programs that can be executed on one or more general-purpose computer processors.

Whether real or simulated, a scenario requires an ego agent to navigate a real or modelled physical context. The ego agent is a real or simulated mobile robot that moves under the control of the stack under testing. The physical context includes static and/or dynamic element(s) that the stack under testing is required to respond to effectively. For example, the mobile robot may be a fully or semi-autonomous vehicle under the control of the stack (the ego vehicle). The physical context may comprise a static road layout and a given set of environmental conditions (e.g. weather, time of day, lighting conditions, humidity, pollution/particulate level etc.) that could be maintained or varied as the scenario progresses. An interactive scenario additionally includes one or more other agents (“external” agent(s), e.g. other vehicles, pedestrians, cyclists, animals etc.).

The following examples consider applications to autonomous vehicle testing. However, the principles apply equally to other forms of mobile robot.

Scenarios may be represented or defined at different levels of abstraction. More abstracted scenarios accommodate a greater degree of variation. For example, a “cut-in scenario” or a “lane change scenario” are examples of highly abstracted scenarios, characterized by a maneuver or behaviour of interest, that accommodate many variations (e.g. different agent starting locations and speeds, road layout, environmental conditions etc.). A “scenario run” refers to a concrete occurrence of an agent(s) navigating a physical context, optionally in the presence of one or more other agents. For example, multiple runs of a cut-in or lane change scenario could be performed (in the real-world and/or in a simulator) with different agent parameters (e.g. starting location, speed etc.), different road layouts, different environmental conditions, and/or different stack configurations etc. The terms “run” and “instance” are used interchangeably in this context.

In the following examples, the performance of the stack is assessed, at least in part, by evaluating the behaviour of the ego agent in the test oracle against a given set of performance evaluation rules, over the course of one or more runs. The rules are applied to “ground truth” of the (or each) scenario run which, in general, simply means an appropriate representation of the scenario run (including the behaviour of the ego agent) that is taken as authoritative for the purpose of testing. Ground truth is inherent to simulation; a simulator computes a sequence of scenario states, which is, by definition, a perfect, authoritative representation of the simulated scenario run. In a real-world scenario run, a “perfect” representation of the scenario run does not exist in the same sense; nevertheless, suitably informative ground truth can be obtained in numerous ways, e.g. based on manual annotation of on-board sensor data, automated/semi-automated annotation of such data (e.g. using offline/non-real time processing), and/or using external information sources (such as external sensors, maps etc.) etc.

The scenario ground truth typically includes a “trace” of the ego agent and any other (salient) agent(s) as applicable. A trace is a history of an agent's location and motion over the course of a scenario. There are many ways a trace can be represented. Trace data will typically include spatial and motion data of an agent within the environment. The term is used in relation to both real scenarios (with real-world traces) and simulated scenarios (with simulated traces). The trace typically records an actual trajectory realized by the agent in the scenario. With regards to terminology, a “trace” and a “trajectory” may contain the same or similar types of information (such as a series of spatial and motion states over time). The term trajectory is generally favoured in the context of planning (and can refer to future/predicted trajectories), whereas the term trace is generally favoured in relation to past behaviour in the context of testing/evaluation.

In a simulation context, a “scenario description” is provided to a simulator as input. For example, a scenario description may be encoded using a scenario description language (SDL), or in any other form that can be consumed by a simulator. A scenario description is typically a more abstract representation of a scenario, that can give rise to multiple simulated runs. Depending on the implementation, a scenario description may have one or more configurable parameters that can be varied to increase the degree of possible variation. The degree of abstraction and parameterization is a design choice. For example, a scenario description may encode a fixed layout, with parameterized environmental conditions (such as weather, lighting etc.). Further abstraction is possible, however, e.g. with configurable road parameter(s) (such as road curvature, lane configuration etc.). The input to the simulator comprises the scenario description together with a chosen set of parameter value(s) (as applicable). The latter may be referred to as a parameterization of the scenario. The configurable parameter(s) define a parameter space (also referred to as the scenario space), and the parameterization corresponds to a point in the parameter space. In this context, a “scenario instance” may refer to an instantiation of a scenario in a simulator based on a scenario description and (if applicable) a chosen parameterization.

For conciseness, the term scenario may also be used to refer to a scenario run, as well a scenario in the more abstracted sense. The meaning of the term scenario will be clear from the context in which it is used.

Trajectory planning is an important function in the present context, and the terms “trajectory planner”, “trajectory planning system” and “trajectory planning stack” may be used interchangeably herein to refer to a component or components that can plan trajectories for a mobile robot into the future. Trajectory planning decisions ultimately determine the actual trajectory realized by the ego agent (although, in some testing contexts, this may be influenced by other factors, such as the implementation of those decisions in the control stack, and the real or modelled dynamic response of the ego agent to the resulting control signals).

A trajectory planner may be tested in isolation, or in combination with one or more other systems (e.g. perception, prediction and/or control). Within a full stack, planning generally refers to higher-level autonomous decision-making capability (such as trajectory planning), whilst control generally refers to the lower-level generation of control signals for carrying out those autonomous decisions. However, in the context of performance testing, the term control is also used in the broader sense. For the avoidance of doubt, when a trajectory planner is said to control an ego agent in simulation, that does not necessarily imply that a control system (in the narrower sense) is tested in combination with the trajectory planner.

### Example AV Stack

To provide relevant context to the described embodiments, further details of an example form of AV stack will now be described.

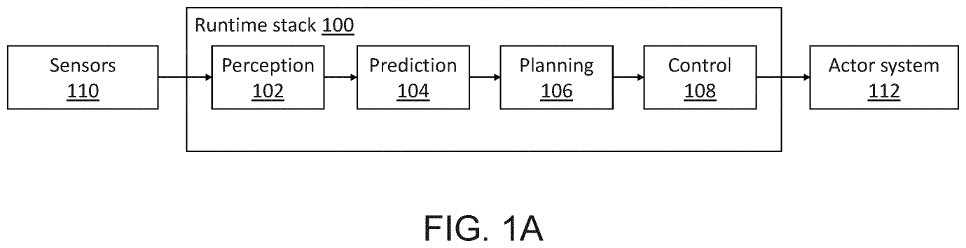

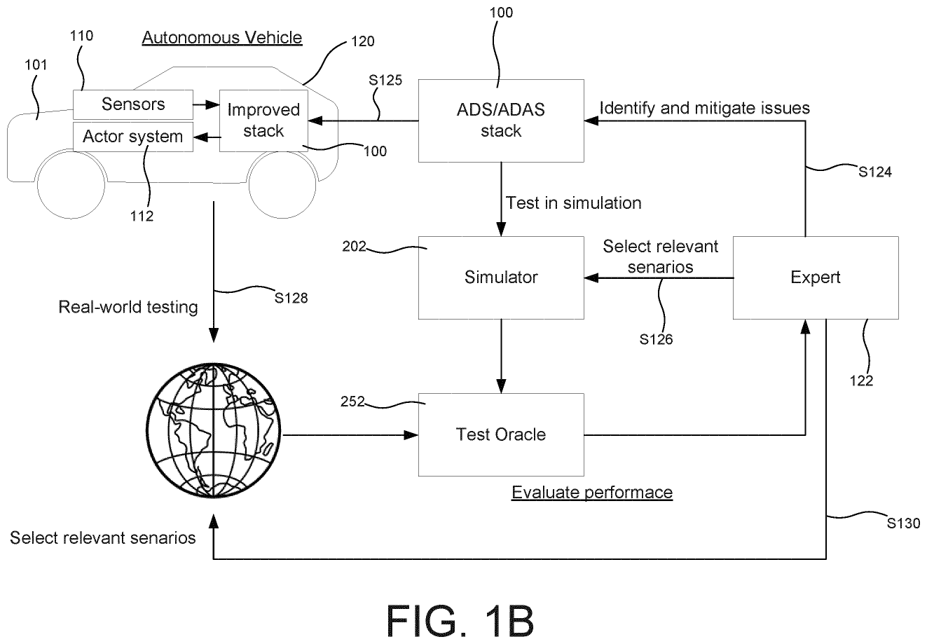

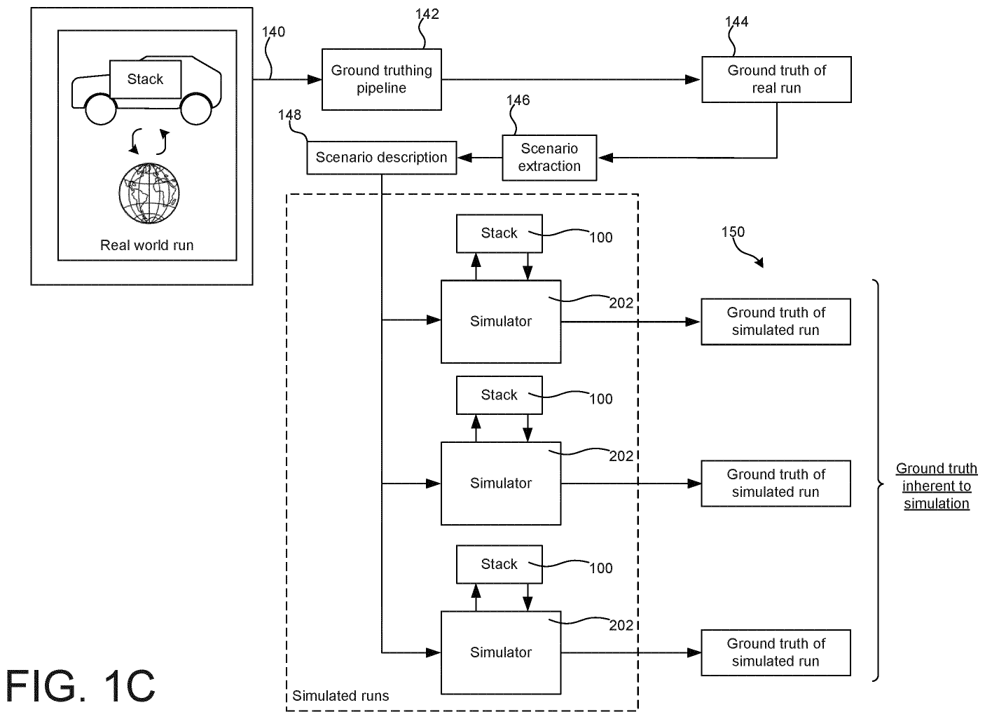

FIG. 1A shows a highly schematic block diagram of an AV runtime stack 100. The run time stack 100 is shown to comprise a perception (sub-)system 102, a prediction (sub-)system 104, a planning (sub-)system (planner) 106 and a control (sub-)system (controller) 108. As noted, the term (sub-)stack may also be used to describe the aforementioned components 102-108.

In a real-world context, the perception system 102 receives sensor outputs from an on-board sensor system 110 of the AV, and uses those sensor outputs to detect external agents and measure their physical state, such as their position, velocity, acceleration etc. The on-board sensor system 110 can take different forms but generally comprises a variety of sensors such as image capture devices (cameras/optical sensors), lidar and/or radar unit(s), satellite-positioning sensor(s) (GPS etc.), motion/inertial sensor(s) (accelerometers, gyroscopes etc.) etc. The onboard sensor system 110 thus provides rich sensor data from which it is possible to extract detailed information about the surrounding environment, and the state of the AV and any external actors (vehicles, pedestrians, cyclists etc.) within that environment. The sensor outputs typically comprise sensor data of multiple sensor modalities such as stereo images from one or more stereo optical sensors, lidar, radar etc. Sensor data of multiple sensor modalities may be combined using filters, fusion components etc.

The perception system 102 typically comprises multiple perception components which co-operate to interpret the sensor outputs and thereby provide perception outputs to the prediction system 104.

In a simulation context, depending on the nature of the testing—and depending, in particular, on where the stack 100 is “sliced” for the purpose of testing (see below)—it may or may not be necessary to model the on-board sensor system 100. With higher-level slicing, simulated sensor data is not required therefore complex sensor modelling is not required.

The perception outputs from the perception system 102 are used by the prediction system 104 to predict future behaviour of external actors (agents), such as other vehicles in the vicinity of the AV.

Predictions computed by the prediction system 104 are provided to the planner 106, which uses the predictions to make autonomous driving decisions to be executed by the AV in a given driving scenario. The inputs received by the planner 106 would typically indicate a drivable area and would also capture predicted movements of any external agents (obstacles, from the AV's perspective) within the drivable area. The driveable area can be determined using perception outputs from the perception system 102 in combination with map information, such as an HD (high definition) map.

A core function of the planner 106 is the planning of trajectories for the AV (ego trajectories), taking into account predicted agent motion. This may be referred to as trajectory planning. A trajectory is planned in order to carry out a desired goal within a scenario. The goal could for example be to enter a roundabout and leave it at a desired exit; to overtake a vehicle in front; or to stay in a current lane at a target speed (lane following). The goal may, for example, be determined by an autonomous route planner (not shown).

The controller 108 executes the decisions taken by the planner 106 by providing suitable control signals to an on-board actor system 112 of the AV. In particular, the planner 106 plans trajectories for the AV and the controller 108 generates control signals to implement the planned trajectories. Typically, the planner 106 will plan into the future, such that a planned trajectory may only be partially implemented at the control level before a new trajectory is planned by the planner 106. The actor system 112 includes “primary” vehicle systems, such as braking, acceleration and steering systems, as well as secondary systems (e.g. signalling, wipers, headlights etc.).

Note, there may be a distinction between a planned trajectory at a given time instant, and the actual trajectory followed by the ego agent. Planning systems typically operate over a sequence of planning steps, updating the planned trajectory at each planning step to account for any changes in the scenario since the previous planning step (or, more precisely, any changes that deviate from the predicted changes). The planning system 106 may reason into the future, such that the planned trajectory at each planning step extends beyond the next planning step. Any individual planned trajectory may, therefore, not be fully realized (if the planning system 106 is tested in isolation, in simulation, the ego agent may simply follow the planned trajectory exactly up to the next planning step; however, as noted, in other real and simulation contexts, the planned trajectory may not be followed exactly up to the next planning step, as the behaviour of the ego agent could be influenced by other factors, such as the operation of the control system 108 and the real or modelled dynamics of the ego vehicle). In many testing contexts, the actual trajectory of the ego agent is what ultimately matters; in particular, whether the actual trajectory is safe, as well as other factors such as comfort and progress. However, the rules-based testing approach herein can also be applied to planned trajectories (even if those planned trajectories are not fully or exactly realized by the ego agent). For example, even if the actual trajectory of an agent is deemed safe according to a given set of safety rules, it might be that an instantaneous planned trajectory was unsafe; the fact that the planner 106 was considering an unsafe course of action may be revealing, even if it did not lead to unsafe agent behaviour in the scenario. Instantaneous planned trajectories constitute one form of internal state that can be usefully evaluated, in addition to actual agent behaviour in the simulation. Other forms of internal stack state can be similarly evaluated.

The example of FIG. 1A considers a relatively “modular” architecture, with separable perception, prediction, planning and control systems 102-108. The sub-stack themselves may also be modular, e.g. with separable planning modules within the planning system 106. For example, the planning system 106 may comprise multiple trajectory planning modules that can be applied in different physical contexts (e.g. simple lane driving vs. complex junctions or roundabouts). This is relevant to simulation testing for the reasons noted above, as it allows components (such as the planning system 106 or individual planning modules thereof) to be tested individually or in different combinations. For the avoidance of doubt, with modular stack architectures, the term stack can refer not only to the full stack but to any individual sub-system or module thereof.

The extent to which the various stack functions are integrated or separable can vary significantly between different stack implementations—in some stacks, certain aspects may be so tightly coupled as to be indistinguishable. For example, in other stacks, planning and control may be integrated (e.g. such stacks could plan in terms of control signals directly), whereas other stacks (such as that depicted in FIG. 1A) may be architected in a way that draws a clear distinction between the two (e.g. with planning in terms of trajectories, and with separate control optimizations to determine how best to execute a planned trajectory at the control signal level). Similarly, in some stacks, prediction and planning may be more tightly coupled. At the extreme, in so-called “end-to-end” driving, perception, prediction, planning and control may be essentially inseparable. Unless otherwise indicated, the perception, prediction planning and control terminology used herein does not imply any particular coupling or modularity of those aspects.

It will be appreciated that the term “stack” encompasses software, but can also encompass hardware. In simulation, software of the stack may be tested on a “generic” off-board computer system, before it is eventually uploaded to an on-board computer system of a physical vehicle. However, in “hardware-in-the-loop” testing, the testing may extend to underlying hardware of the vehicle itself. For example, the stack software may be run on the on-board computer system (or a replica thereof) that is coupled to the simulator for the purpose of testing. In this context, the stack under testing extends to the underlying computer hardware of the vehicle. As another example, certain functions of the stack 110 (e.g. perception functions) may be implemented in dedicated hardware. In a simulation context, hardware-in-the loop testing could involve feeding synthetic sensor data to dedicated hardware perception components.

### Example Testing Paradigm

FIG. 1B shows a highly schematic overview of a testing paradigm for autonomous vehicles. An ADS/ADAS stack 100, e.g. of the kind depicted in FIG. 1A, is subject to repeated testing and evaluation in simulation, by running multiple scenario instances in a simulator 202, and evaluating the performance of the stack 100 (and/or individual subs-stacks thereof) in a test oracle 252. The output of the test oracle 252 is informative to an expert 122 (team or individual), allowing them to identify issues in the stack 100 and modify the stack 100 to mitigate those issues (S124). The results also assist the expert 122 in selecting further scenarios for testing (S126), and the process continues, repeatedly modifying, testing and evaluating the performance of the stack 100 in simulation. The improved stack 100 is eventually incorporated (S125) in a real-world AV 101, equipped with a sensor system 110 and an actor system 112. The improved stack 100 typically includes program instructions (software) executed in one or more computer processors of an on-board computer system of the vehicle 101 (not shown). The software of the improved stack is uploaded to the AV 101 at step S125. Step 125 may also involve modifications to the underlying vehicle hardware.

On board the AV 101, the improved stack 100 receives sensor data from the sensor system 110 and outputs control signals to the actor system 112. Real-world testing (S128) can be used in combination with simulation-based testing. For example, having reached an acceptable level of performance though the process of simulation testing and stack refinement, appropriate real-world scenarios may be selected (S130), and the performance of the AV 101 in those real scenarios may be captured and similarly evaluated in the test oracle 252.

Scenarios can be obtained for the purpose of simulation in various ways, including manual encoding. The system is also capable of extracting scenarios for the purpose of simulation from real-world runs, allowing real-world situations and variations thereof to be re-created in the simulator 202.

FIG. 1C shows a highly schematic block diagram of a scenario extraction pipeline. Data 140 of a real-world run is passed to a ‘ground-truthing’ pipeline 142 for the purpose of generating scenario ground truth. The run data 140 could comprise, for example, sensor data and/or perception outputs captured/generated on board one or more vehicles (which could be autonomous, human-driven or a combination thereof), and/or data captured from other sources such external sensors (CCTV etc.). The run data is processed within the ground truthing pipeline 142, in order to generate appropriate ground truth 144 (trace(s) and contextual data) for the real-world run. As discussed, the ground-truthing process could be based on manual annotation of the ‘raw’ run data 142, or the process could be entirely automated (e.g. using offline perception method(s)), or a combination of manual and automated ground truthing could be used. For example, 3D bounding boxes may be placed around vehicles and/or other agents captured in the run data 140, in order to determine spatial and motion states of their traces. A scenario extraction component 146 receives the scenario ground truth 144, and processes the scenario ground truth 144 to extract a more abstracted scenario description 148 that can be used for the purpose of simulation. The scenario description 148 is consumed by the simulator 202, allowing multiple simulated runs to be performed. The simulated runs are variations of the original real-world run, with the degree of possible variation determined by the extent of abstraction. Ground truth 150 is provided for each simulated run.

### Testing Pipeline:

Further details of the testing pipeline and the test oracle 252 will now be described. The examples that follow focus on simulation-based testing. However, as noted, the test oracle 252 can equally be applied to evaluate stack performance on real scenarios, and the relevant description below applies equally to real scenarios. The following description refers to the stack 100 of FIG. 1A by way of example. However, as noted, the testing pipeline 200 is highly flexible and can be applied to any stack or sub-stack operating at any level of autonomy.

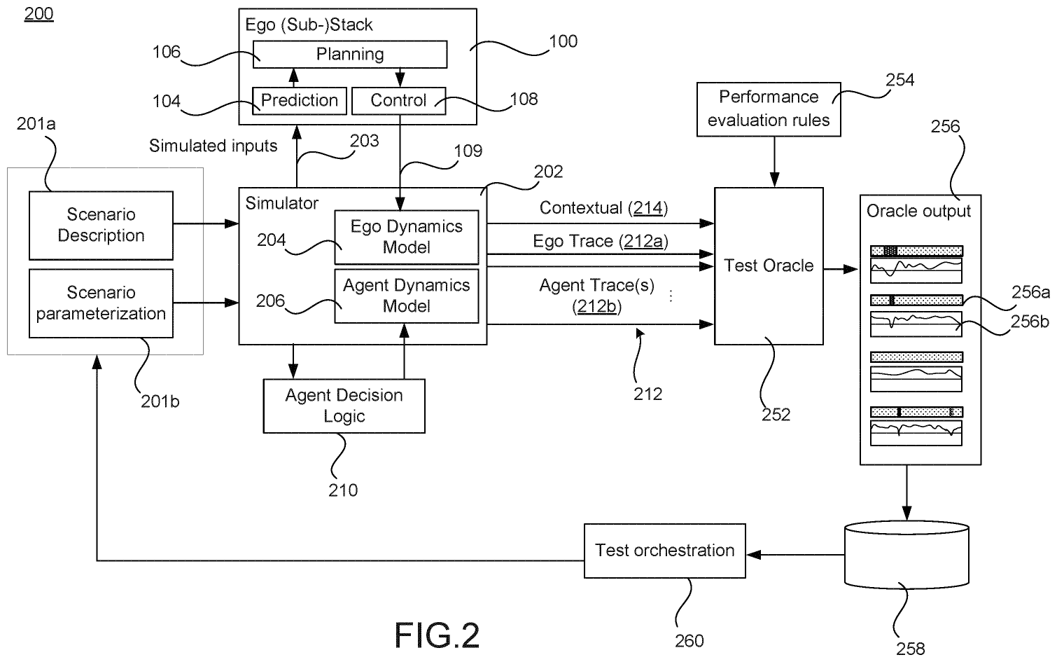

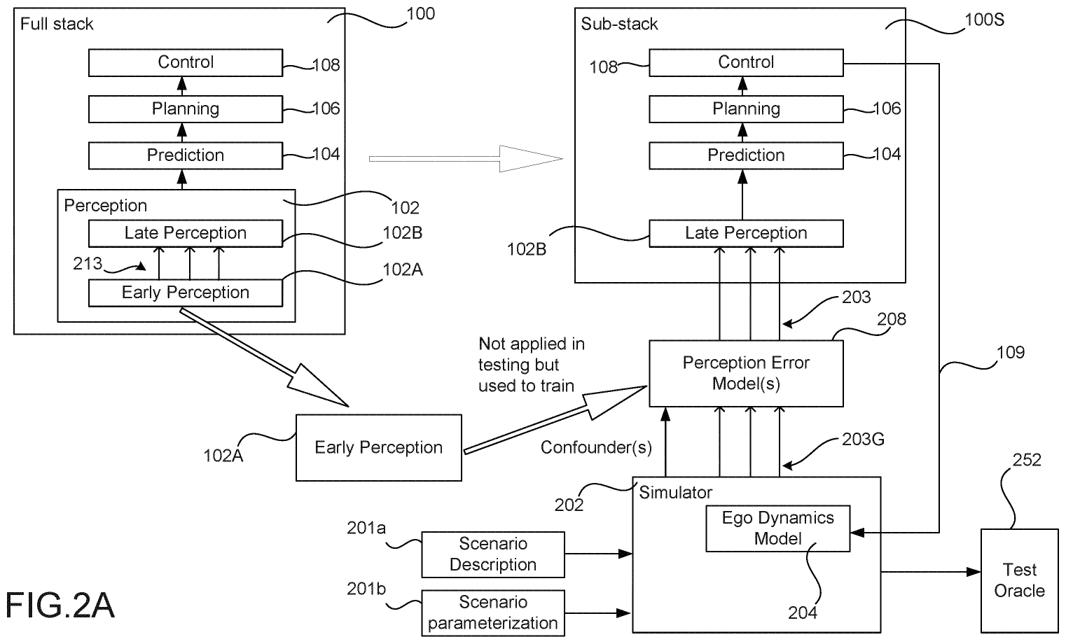

FIG. 2 shows a schematic block diagram of the testing pipeline, denoted by reference numeral 200. The testing pipeline 200 is shown to comprise the simulator 202 and the test oracle 252. The simulator 202 runs simulated scenarios for the purpose of testing all or part of an AV run time stack 100, and the test oracle 252 evaluates the performance of the stack (or sub-stack) on the simulated scenarios. As discussed, it may be that only a sub-stack of the run-time stack is tested, but for simplicity, the following description refers to the (full) AV stack 100 throughout. However, the description applies equally to a sub-stack in place of the full stack 100. The term “slicing” is used herein to the selection of a set or subset of stack components for testing.

As described previously, the idea of simulation-based testing is to run a simulated driving scenario that an ego agent must navigate under the control of the stack 100 being tested. Typically, the scenario includes a static drivable area (e.g. a particular static road layout) that the ego agent is required to navigate, typically in the presence of one or more other dynamic agents (such as other vehicles, bicycles, pedestrians etc.). To this end, simulated inputs 203 are provided from the simulator 202 to the stack 100 under testing.

The slicing of the stack dictates the form of the simulated inputs 203. By way of example, FIG. 2 shows the prediction, planning and control systems 104, 106 and 108 within the AV stack 100 being tested. To test the full AV stack of FIG. 1A, the perception system 102 could also be applied during testing. In this case, the simulated inputs 203 would comprise synthetic sensor data that is generated using appropriate sensor model(s) and processed within the perception system 102 in the same way as real sensor data. This requires the generation of sufficiently realistic synthetic sensor inputs (such as photorealistic image data and/or equally realistic simulated lidar/radar data etc.). The resulting outputs of the perception system 102 would, in turn, feed into the higher-level prediction and planning systems 104, 106.

By contrast, so-called “planning-level” simulation would essentially bypass the perception system 102. The simulator 202 would instead provide simpler, higher-level inputs 203 directly to the prediction system 104. In some contexts, it may even be appropriate to bypass the prediction system 104 as well, in order to test the planner 106 on predictions obtained directly from the simulated scenario (i.e. “perfect” predictions).

Between these extremes, there is scope for many different levels of input slicing, e.g. testing only a subset of the perception system 102, such as “later” (higher-level) perception components, e.g. components such as filters or fusion components which operate on the outputs from lower-level perception components (such as object detectors, bounding box detectors, motion detectors etc.).

Whatever form they take, the simulated inputs 203 are used (directly or indirectly) as a basis for decision-making by the planner 108. The controller 108, in turn, implements the planner's decisions by outputting control signals 109. In a real-world context, these control signals would drive the physical actor system 112 of AV. In simulation, an ego vehicle dynamics model 204 is used to translate the resulting control signals 109 into realistic motion of the ego agent within the simulation, thereby simulating the physical response of an autonomous vehicle to the control signals 109.

Alternatively, a simpler form of simulation assumes that the ego agent follows each planned trajectory exactly between planning steps. This approach bypasses the control system 108 (to the extent it is separable from planning) and removes the need for the ego vehicle dynamic model 204. This may be sufficient for testing certain facets of planning.

To the extent that external agents exhibit autonomous behaviour/decision making within the simulator 202, some form of agent decision logic 210 is implemented to carry out those decisions and determine agent behaviour within the scenario. The agent decision logic 210 may be comparable in complexity to the ego stack 100 itself or it may have a more limited decision-making capability. The aim is to provide sufficiently realistic external agent behaviour within the simulator 202 to be able to usefully test the decision-making capabilities of the ego stack 100. In some contexts, this does not require any agent decision making logic 210 at all (open-loop simulation), and in other contexts useful testing can be provided using relatively limited agent logic 210 such as basic adaptive cruise control (ACC). One or more agent dynamics models 206 may be used to provide more realistic agent behaviour if appropriate.

A scenario is run in accordance with a scenario description 201a and (if applicable) a chosen parameterization 201b of the scenario. A scenario typically has both static and dynamic elements which may be “hard coded” in the scenario description 201a or configurable and thus determined by the scenario description 201a in combination with a chosen parameterization 201b. In a driving scenario, the static element(s) typically include a static road layout.

The dynamic element(s) typically include one or more external agents within the scenario, such as other vehicles, pedestrians, bicycles etc.

The extent of the dynamic information provided to the simulator 202 for each external agent can vary. For example, a scenario may be described by separable static and dynamic layers. A given static layer (e.g. defining a road layout) can be used in combination with different dynamic layers to provide different scenario instances. The dynamic layer may comprise, for each external agent, a spatial path to be followed by the agent together with one or both of motion data and behaviour data associated with the path. In simple open-loop simulation, an external actor simply follows the spatial path and motion data defined in the dynamic layer that is non-reactive i.e. does not react to the ego agent within the simulation. Such open-loop simulation can be implemented without any agent decision logic 210. However, in closed-loop simulation, the dynamic layer instead defines at least one behaviour to be followed along a static path (such as an ACC behaviour). In this case, the agent decision logic 210 implements that behaviour within the simulation in a reactive manner, i.e. reactive to the ego agent and/or other external agent(s). Motion data may still be associated with the static path but in this case is less prescriptive and may for example serve as a target along the path. For example, with an ACC behaviour, target speeds may be set along the path which the agent will seek to match, but the agent decision logic 210 might be permitted to reduce the speed of the external agent below the target at any point along the path in order to maintain a target headway from a forward vehicle.

As will be appreciated, scenarios can be described for the purpose of simulation in many ways, with any degree of configurability. For example, the number and type of agents, and their motion information may be configurable as part of the scenario parameterization 201b.

The output of the simulator 202 for a given simulation includes an ego trace 212a of the ego agent and one or more agent traces 212b of the one or more external agents (traces 212). Each trace 212a, 212b is a complete history of an agent's behaviour within a simulation having both spatial and motion components. For example, each trace 212a, 212b may take the form of a spatial path having motion data associated with points along the path such as speed, acceleration, jerk (rate of change of acceleration), snap (rate of change of jerk) etc.

Additional information is also provided to supplement and provide context to the traces 212. Such additional information is referred to as “contextual” data 214. The contextual data 214 pertains to the physical context of the scenario, and can have both static components (such as road layout) and dynamic components (such as weather conditions to the extent they vary over the course of the simulation). To an extent, the contextual data 214 may be “passthrough” in that it is directly defined by the scenario description 201a or the choice of parameterization 201b, and is thus unaffected by the outcome of the simulation. For example, the contextual data 214 may include a static road layout that comes from the scenario description 201a or the parameterization 201b directly. However, typically the contextual data 214 would include at least some elements derived within the simulator 202. This could, for example, include simulated environmental data, such as weather data, where the simulator 202 is free to change weather conditions as the simulation progresses. In that case, the weather data may be time-dependent, and that time dependency will be reflected in the contextual data 214.

The test oracle 252 receives the traces 212 and the contextual data 214, and scores those outputs in respect of a set of performance evaluation rules 254. The performance evaluation rules 254 are shown to be provided as an input to the test oracle 252.

The rules 254 are categorical in nature (e.g. pass/fail-type rules). Certain performance evaluation rules are also associated with numerical performance metrics used to “score” trajectories (e.g. indicating a degree of success or failure or some other quantity that helps explain or is otherwise relevant to the categorical results). The evaluation of the rules 254 is time-based—a given rule may have a different outcome at different points in the scenario. The scoring is also time-based: for each performance evaluation metric, the test oracle 252 tracks how the value of that metric (the score) changes over time as the simulation progresses. The test oracle 252 provides an output 256 comprising a time sequence 256a of categorical (e.g. pass/fail) results for each rule, and a score-time plot 256b for each performance metric, as described in further detail later. The results and scores 256a, 256b are informative to the expert 122 and can be used to identify and mitigate performance issues within the tested stack 100. The test oracle 252 also provides an overall (aggregate) result for the scenario (e.g. overall pass/fail). The output 256 of the test oracle 252 is stored in a test database 258, in association with information about the scenario to which the output 256 pertains. For example, the output 256 may be stored in association with the scenario description 210a (or an identifier thereof), and the chosen parameterization 201b. As well as the time-dependent results and scores, an overall score may also be assigned to the scenario and stored as part of the output 256. For example, an aggregate score for each rule (e.g. overall pass/fail) and/or an aggregate result (e.g. pass/fail) across all of the rules 254.

FIG. 2A illustrates another choice of slicing and uses reference numerals 100 and 100S to denote a full stack and sub-stack respectively. It is the sub-stack 100S that would be subject to testing within the testing pipeline 200 of FIG. 2.

A number of “later” perception components 102B form part of the sub-stack 100S to be tested and are applied, during testing, to simulated perception inputs 203. The later perception components 102B could, for example, include filtering or other fusion components that fuse perception inputs from multiple earlier perception components.

In the full stack 100, the later perception components 102B would receive actual perception inputs 213 from earlier perception components 102A. For example, the earlier perception components 102A might comprise one or more 2D or 3D bounding box detectors, in which case the simulated perception inputs provided to the late perception components could include simulated 2D or 3D bounding box detections, derived in the simulation via ray tracing. The earlier perception components 102A would generally include component(s) that operate directly on sensor data. With the slicing of FIG. 2A, the simulated perception inputs 203 would correspond in form to the actual perception inputs 213 that would normally be provided by the earlier perception components 102A. However, the earlier perception components 102A are not applied as part of the testing, but are instead used to train one or more perception error models 208 that can be used to introduce realistic error, in a statistically rigorous manner, into the simulated perception inputs 203 that are fed to the later perception components 102B of the sub-stack 100 under testing.

Such perception error models may be referred to as Perception Statistical Performance Models (PSPMs) or, synonymously, “PRISMs”. Further details of the principles of PSPMs, and suitable techniques for building and training them, may be bound in International Patent Publication Nos. WO2021037763 WO2021037760, WO2021037765, WO2021037761, and WO2021037766, each of which is incorporated herein by reference in its entirety. The idea behind PSPMs is to efficiently introduce realistic errors into the simulated perception inputs provided to the sub-stack 100S (i.e. that reflect the kind of errors that would be expected were the earlier perception components 102A to be applied in the real-world). In a simulation context, “perfect” ground truth perception inputs 203G are provided by the simulator, but these are used to derive more realistic perception inputs 203 with realistic error introduced by the perception error models(s) 208.

As described in the aforementioned reference, a PSPM can be dependent on one or more variables representing physical condition(s) (“confounders”), allowing different levels of error to be introduced that reflect different possible real-world conditions. Hence, the simulator 202 can simulate different physical conditions (e.g. different weather conditions) by simply changing the value of a weather confounder(s), which will, in turn, change how perception error is introduced.

The later perception components 102b within the sub-stack 100S process the simulated perception inputs 203 in exactly the same way as they would process the real-world perception inputs 213 within the full stack 100, and their outputs, in turn, drive prediction, planning and control.

Alternatively, PRISMs can be used to model the entire perception system 102, including the late perception components 208, in which case a PSPM(s) is used to generate realistic perception output that are passed as inputs to the prediction system 104 directly.

Depending on the implementation, there may or may not be deterministic relationship between a given scenario parameterization 201b and the outcome of the simulation for a given configuration of the stack 100 (i.e. the same parameterization may or may not always lead to the same outcome for the same stack 100). Non-determinism can arise in various ways. For example, when simulation is based on PRISMs, a PRISM might model a distribution over possible perception outputs at each given time step of the scenario, from which a realistic perception output is sampled probabilistically. This leads to non-deterministic behaviour within the simulator 202, whereby different outcomes may be obtained for the same stack 100 and scenario parameterization because different perception outputs are sampled. Alternatively, or additionally, the simulator 202 may be inherently non-deterministic, e.g. weather, lighting or other environmental conditions may be randomized/probabilistic within the simulator 202 to a degree. As will be appreciated, this is a design choice: in other implementations, varying environmental conditions could instead be fully specified in the parameterization 201b of the scenario. With non-deterministic simulation, multiple scenario instances could be run for each parameterization. An aggregate pass/fail result could be assigned to a particular choice of parameterization 201b, e.g. as a count or percentage of pass or failure outcomes.

A test orchestration component 260 is responsible for selecting scenarios for the purpose of simulation. For example, the test orchestration component 260 may select scenario descriptions 201a and suitable parameterizations 201b automatically, based on the test oracle outputs 256 from previous scenarios.

### Test Oracle Rules:

The performance evaluation rules 254 are constructed as computational graphs (rule trees) to be applied within the test oracle. Unless otherwise indicated, the term “rule tree” herein refers to the computational graph that is configured to implement a given rule. Each rule is constructed as a rule tree, and a set of multiple rules may be referred to as a “forest” of multiple rule trees.

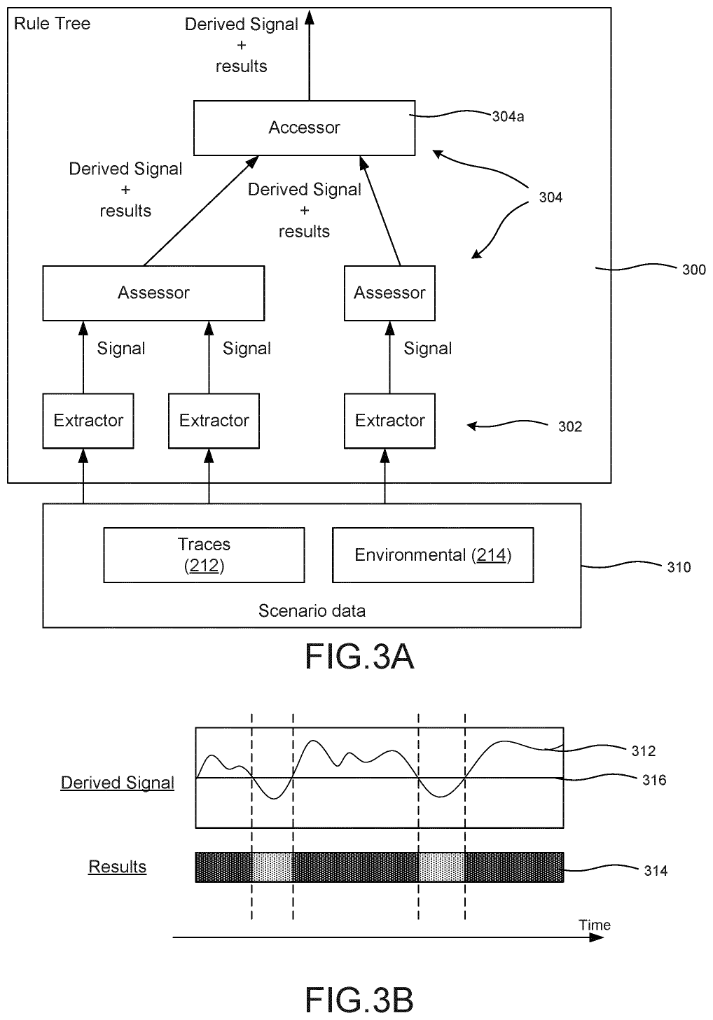

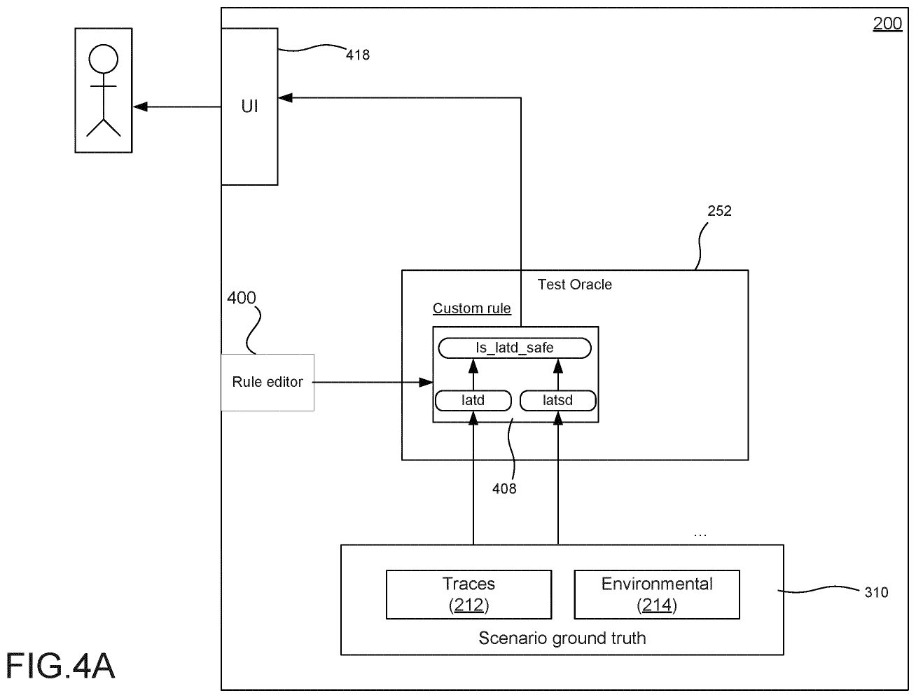

FIG. 3A shows an example of a rule tree 300 constructed from a combination of extractor nodes (leaf objects) 302 and assessor nodes (non-leaf objects) 304. Each extractor node 302 extracts a time-varying numerical (e.g. floating point) signal (score) from a set of scenario data 310. The scenario data 310 is a form of scenario ground truth, in the sense laid out above, and may be referred to as such. The scenario data 310 has been obtained by deploying a trajectory planner (such as the planner 106 of FIG. 1A) in a real or simulated scenario, and is shown to comprise ego and agent traces 212 as well as contextual data 214. In the simulation context of FIG. 2 or FIG. 2A, the scenario ground truth 310 is provided as an output of the simulator 202.

Each assessor node 304 is shown to have at least one child object (node), where each child object is one of the extractor nodes 302 or another one of the assessor nodes 304. Each assessor node receives output(s) from its child node(s) and applies an assessor function to those output(s). The output of the assessor function is a time-series of categorical results. The following examples consider simple binary pass/fail results, but the techniques can be readily extended to non-binary results. Each assessor function assesses the output(s) of its child node(s) against a predetermined atomic rule. Such rules can be flexibly combined in accordance with a desired safety model.

In addition, each assessor node 304 derives a time-varying numerical signal from the output(s) of its child node(s), which is related to the categorical results by a threshold condition (see below).

A top-level root node 304a is an assessor node that is not a child node of any other node. The top-level node 304a outputs a final sequence of results, and its descendants (i.e. nodes that are direct or indirect children of the top-level node 304a) provide the underlying signals and intermediate results.

FIG. 3B visually depicts an example of a derived signal 312 and a corresponding time-series of results 314 computed by an assessor node 304. The results 314 are correlated with the derived signal 312, in that a pass result is returned when (and only when) the derived signal exceeds a failure threshold 316. As will be appreciated, this is merely one example of a threshold condition that relates a time-sequence of results to a corresponding signal.

Signals extracted directly from the scenario ground truth 310 by the extractor nodes 302 may be referred to as “raw” signals, to distinguish from “derived” signals computed by assessor nodes 304. Results and raw/derived signals may be discretized in time.

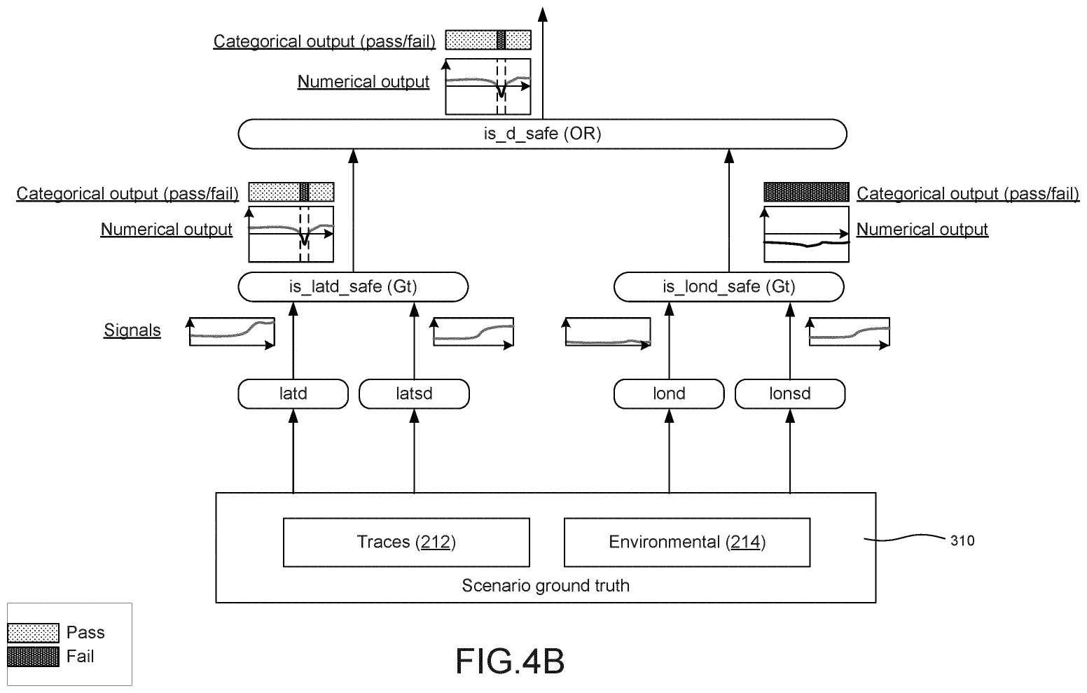

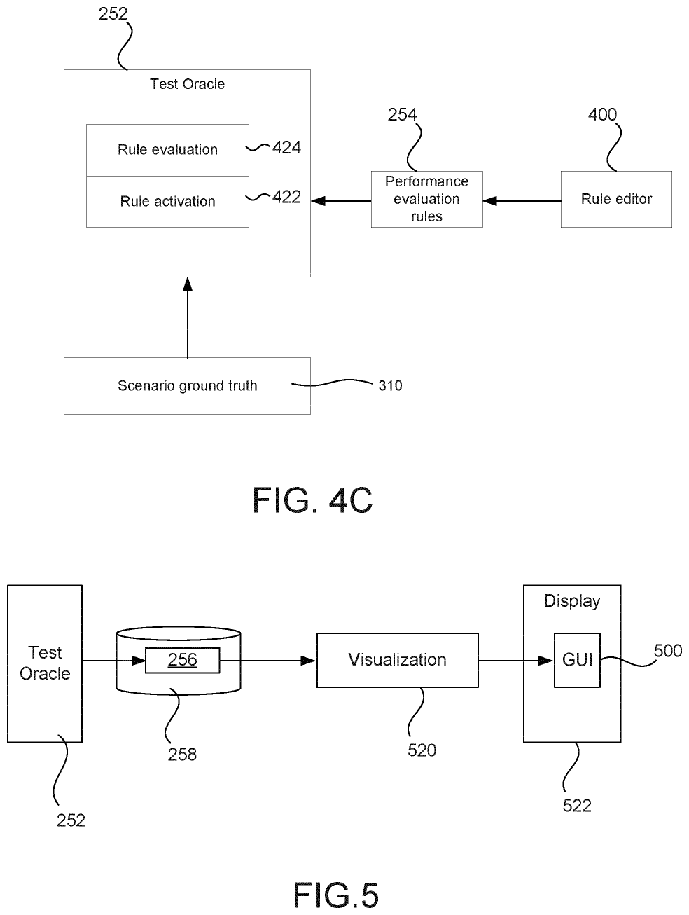

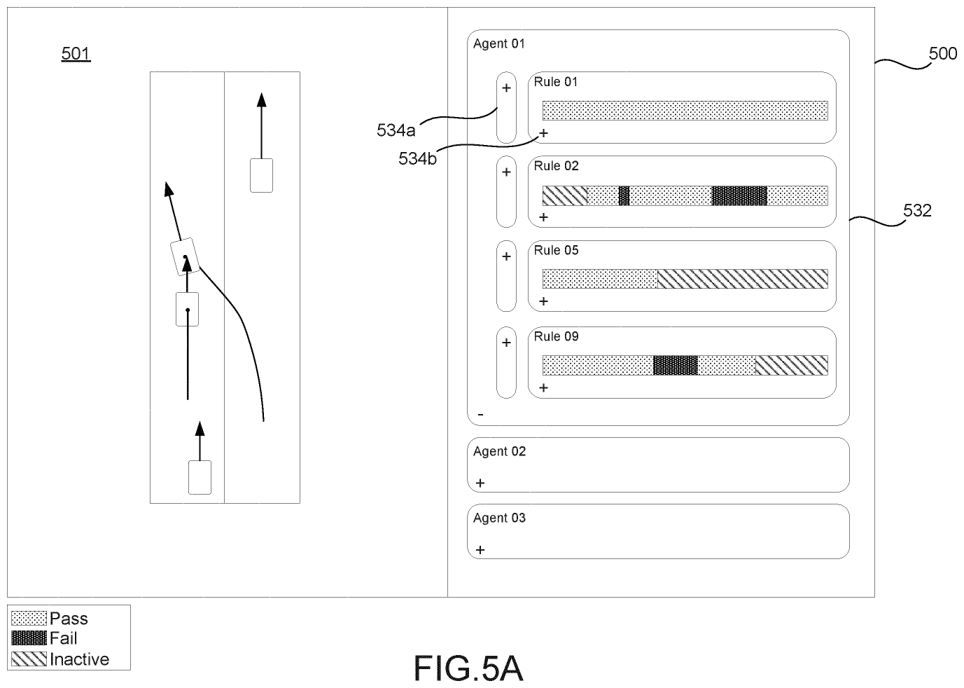

FIG. 4A shows an example of a rule tree implemented within the testing platform 200.

A rule editor 400 is provided for constructing rules to be implemented with the test oracle 252. The rule editor 400 receives rule creation inputs from a user (who may or may not be the end-user of the system). In the present example, the rule creation inputs are coded in a domain specific language (DSL) and define at least one rule graph 408 to be implemented within the test oracle 252. The rules are logical rules in the following examples, with TRUE and FALSE representing pass and failure respectively (as will be appreciated, this is purely a design choice).

The following examples consider rules that are formulated using combinations of atomic logic predicates. Examples of basic atomic predicates include elementary logic gates (OR, AND etc.), and logical functions such as “greater than”, (Gt(a,b)) (which returns TRUE when a is greater than b, and false otherwise).

A Gt function is to implement a safe lateral distance rule between an ego agent and another agent in the scenario (having agent identifier “other_agent_id”). Two extractor nodes (latd, latsd) apply LateralDistance and LateralSafeDistance extractor functions respectively. Those functions operate directly on the scenario ground truth 310 to extract, respectively, a time-varying lateral distance signal (measuring a lateral distance between the ego agent and the identified other agent), and a time-varying safe lateral distance signal for the ego agent and the identified other agent. The safe lateral distance signal could depend on various factors, such as the speed of the ego agent and the speed of the other agent (captured in the traces 212), and environmental conditions (e.g. weather, lighting, road type etc.) captured in the contextual data 214.

An assessor node (is_latd_safe) is a parent to the latd and latsd extractor nodes, and is mapped to the Gt atomic predicate. Accordingly, when the rule tree 408 is implemented, the is_latd_safe assessor node applies the Gt function to the outputs of the latd and latsd extractor nodes, in order to compute a true/false result for each timestep of the scenario, returning TRUE for each time step at which the latd signal exceeds the latsd signal and FALSE otherwise. In this manner, a “safe lateral distance” rule has been constructed from atomic extractor functions and predicates; the ego agent fails the safe lateral distance rule when the lateral distance reaches or falls below the safe lateral distance threshold. As will be appreciated, this is a very simple example of a rule tree. Rules of arbitrary complexity can be constructed according to the same principles.

The test oracle 252 applies the rule tree 408 to the scenario ground truth 310, and provides the results via a user interface (UI) 418.

FIG. 4B shows an example of a rule tree that includes a lateral distance branch corresponding to that of FIG. 4A. Additionally, the rule tree includes a longitudinal distance branch, and a top-level OR predicate (safe distance node, is_d_safe) to implement a safe distance metric. Similar to the lateral distance branch, the longitudinal distance brand extracts longitudinal distance and longitudinal distance threshold signals from the scenario data (extractor nodes lond and lonsd respectively), and a longitudinal safety assessor node (is_lond_safe) returns TRUE when the longitudinal distance is above the safe longitudinal distance threshold. The top-level OR node returns TRUE when one or both of the lateral and longitudinal distances is safe (below the applicable threshold), and FALSE if neither is safe. In this context, it is sufficient for only one of the distances to exceed the safety threshold (e.g. if two vehicles are driving in adjacent lanes, their longitudinal separation is zero or close to zero when they are side-by-side; but that situation is not unsafe if those vehicles have sufficient lateral separation).

The numerical output of the top-level node could, for example, be a time-varying robustness score.

Different rule trees can be constructed, e.g. to implement different rules of a given safety model, to implement different safety models, or to apply rules selectively to different scenarios (in a given safety model, not every rule will necessarily be applicable to every scenario; with this approach, different rules or combinations of rules can be applied to different scenarios). Within this framework, rules can also be constructed for evaluating comfort (e.g. based on instantaneous acceleration and/or jerk along the trajectory), progress (e.g. based on time taken to reach a defined goal) etc.

The above examples consider simple logical predicates evaluated on results or signals at a single time instance, such as OR, AND, Gt etc. However, in practice, it may be desirable to formulate certain rules in terms of temporal logic.

Hekmatnejad et al., “Encoding and Monitoring Responsibility Sensitive Safety Rules for Automated Vehicles in Signal Temporal Logic” (2019), MEMOCODE '19: Proceedings of the 17th ACM-IEEE International Conference on Formal Methods and Models for System Design (incorporated herein by reference in its entirety) discloses a signal temporal logic (STL) encoding of the RSS safety rules. Temporal logic provides a formal framework for constructing predicates that are qualified in terms of time. This means that the result computed by an assessor at a given time instant can depend on results and/or signal values at another time instant(s).

For example, a requirement of the safety model may be that an ego agent responds to a certain event within a set time frame. Such rules can be encoded in a similar manner, using temporal logic predicates within the rule tree.

In the above examples, the performance of the stack 100 is evaluated at each time step of a scenario. An overall test result (e.g. pass/fail) can be derived from this—for example, certain rules (e.g. safety-critical rules) may result in an overall failure if the rule is failed at any time step within the scenario (that is, the rule must be passed at every time step to obtain an overall pass on the scenario). For other types of rule, the overall pass/fail criteria may be “softer” (e.g. failure may only be triggered for a certain rule if that rule is failed over some number of sequential time steps), and such criteria may be context dependent.

### Rule Evaluation Hierarchy:

FIG. 4C schematically depicts a hierarchy of rule evaluation implemented within the test oracle 252. A set of rules 254 is received for implementation in the test oracle 252.

Certain rules apply only to the ego agent (an example being a comfort rule that assesses whether or not some maximum acceleration or jerk threshold is exceeded by the ego agent at any given time instant).

Other rules pertain to the interaction of the ego agent with other agents (for example, a “no collision” rule or the safe distance rule considered above). Each such rule is evaluated in a pairwise fashion between the ego agent and each other agent. As another example, a “pedestrian emergency braking” rule may only be activated when a pedestrian walks out in front of the ego vehicle, and only in respect of that pedestrian agent.

Not every rule will necessarily be applicable to every scenario, and some rules may only be applicable for part of a scenario. Rule activation logic 422 within the test oracle 422 determines if and when each of the rules 254 is applicable to the scenario in question, and selectively activates rules as and when they apply. A rule may, therefore, remain active for the entirety of a scenario, may never be activated for a given scenario, or may be activated for only some of the scenario. Moreover, a rule may be evaluated for different numbers of agents at different points in the scenario. Selectively activating rules in this manner can significantly increase the efficiency of the test oracle 252.

The activation or deactivation of a given rule may be dependent on the activation/deactivation of one or more other rules. For example, an “optimal comfort” rule may be deemed inapplicable when the pedestrian emergency braking rule is activated (because the pedestrian's safety is the primary concern), and the former may be deactivated whenever the latter is active.

Rule evaluation logic 424 evaluates each active rule for any time period(s) it remains active. Each interactive rule is evaluated in a pairwise fashion between the ego agent and any other agent to which it applies.

There may also be a degree of interdependency in the application of the rules. For example, another way to address the relationship between a comfort rule and an emergency braking rule would be to increase a jerk/acceleration threshold of the comfort rule whenever the emergency braking rule is activated for at least one other agent.

Whilst pass/fail results have been considered, rules may be non-binary. For example, two categories for failure—“acceptable” and “unacceptable”—may be introduced. Again, considering the relationship between a comfort rule and an emergency braking rule, an acceptable failure on a comfort rule may occur when the rule is failed but at a time when an emergency braking rule was active. Interdependency between rules can, therefore, be handled in various ways.

The activation criteria for the rules 254 can be specified in the rule creation code provided to the rule editor 400, as can the nature of any rule interdependencies and the mechanism(s) for implementing those interdependencies.

### Graphical User Interface:

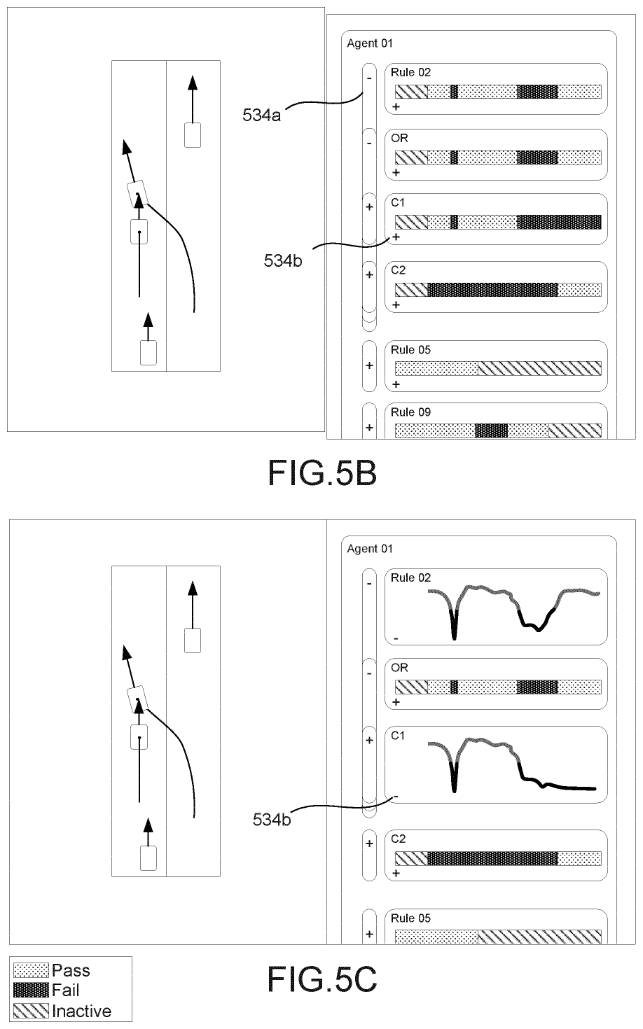

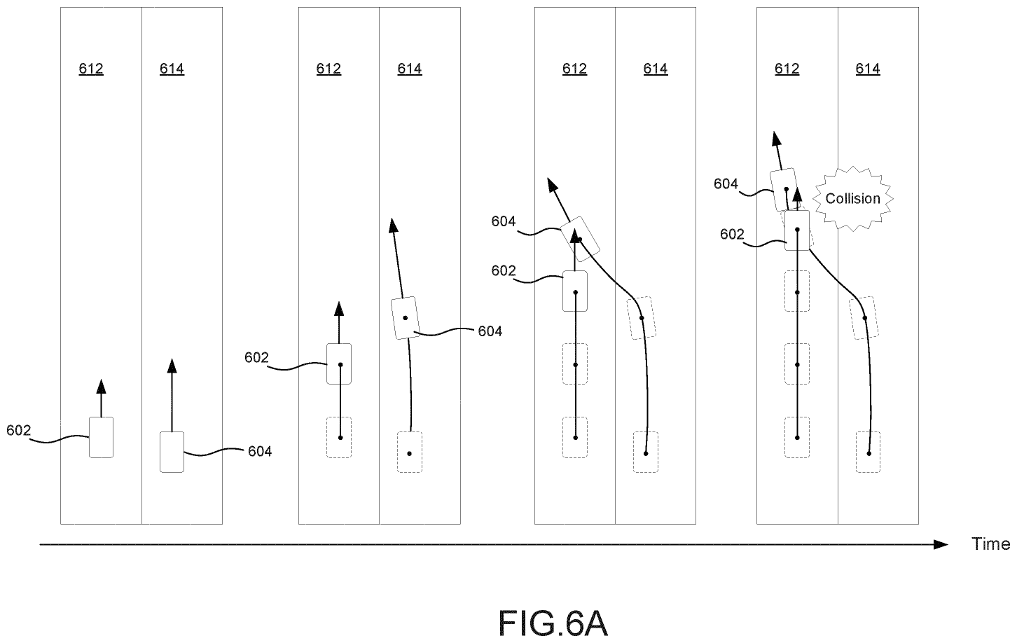

FIG. 5 shows a schematic block diagram of a visualization component 520. The visualization component is shown having an input connected to the test database 258 for rendering the outputs 256 of the test oracle 252 on a graphical user interface (GUI) 500. The GUI is rendered on a display system 522.

FIG. 5A shows an example view of the GUI 500. The view pertains to a particular scenario containing multiple agents. In this example, the test oracle output 526 pertains to multiple external agents, and the results are organized according to agent. For each agent, a time-series of results is available for each rule applicable to that agent at some point in the scenario. The visual representation of the results is referred to as a “rule timeline”. In the depicted example, a summary view has been selected for “Agent 01”, causing the “top-level” results computed to be displayed for each applicable rule. There are the top-level results computed at the root node of each rule tree. Colour coding is used to differentiate between periods when the rule is inactive for that agent, active and passes, and active and failed.

A first selectable element 534a is provided for each time-series of results. This allows lower-level results of the rule tree to be accessed, i.e. as computed lower down in the rule tree.

FIG. 5B shows a first expanded view of the results for “Rule 02”, in which the results of lower-level nodes are also visualized. For example, for the “safe distance” rule of FIG. 4B, the results of the “is_latd_safe node” and the “is_lond_safe” nodes may be visualized (labelled “C1” and “C2” in FIG. 5B). In the first expanded view of Rule 02, it can be seen that success/failure on Rule 02 is defined by a logical OR relationship between results C1 and C2; Rule 02 is failed only when failure is obtained on both C1 and C2 (as in the “safe distance” rule above).

A second selectable element 534b is provided for each time-series of results, that allows the associated numerical performance scores to be accessed.

FIG. 5C shows a second expanded view, in which the results for Rule 02 and the “C1” results have been expanded to reveal the associated scores for time period(s) in which those rules are active for Agent 01. The scores are displayed as a visual score-time plot that is similarly colour coded to denote pass/fail.

### Example Scenarios

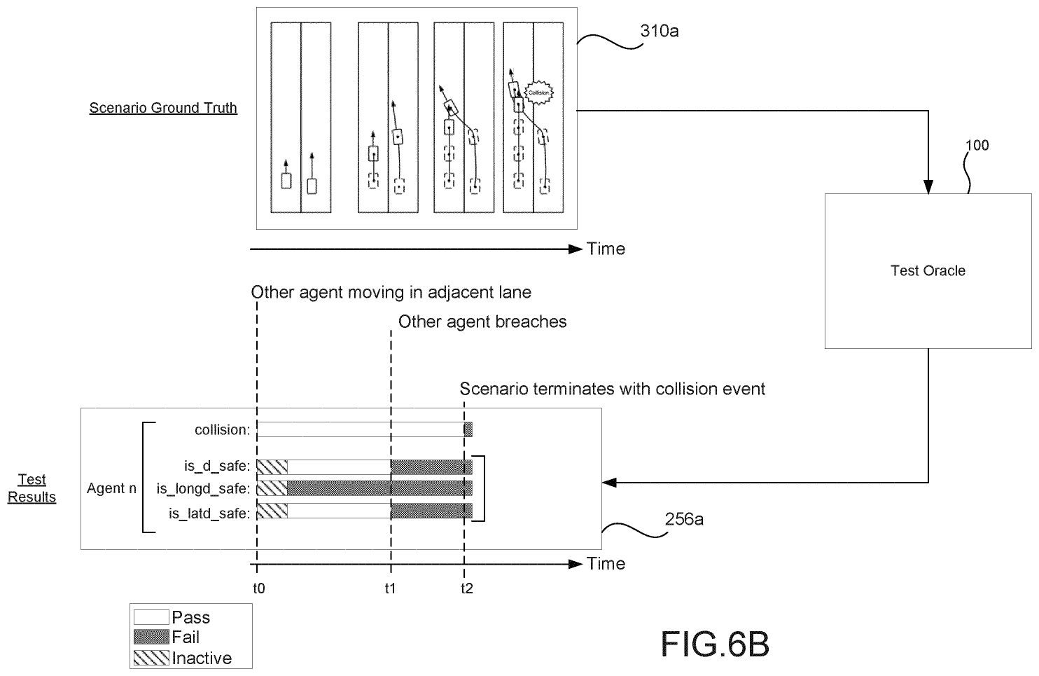

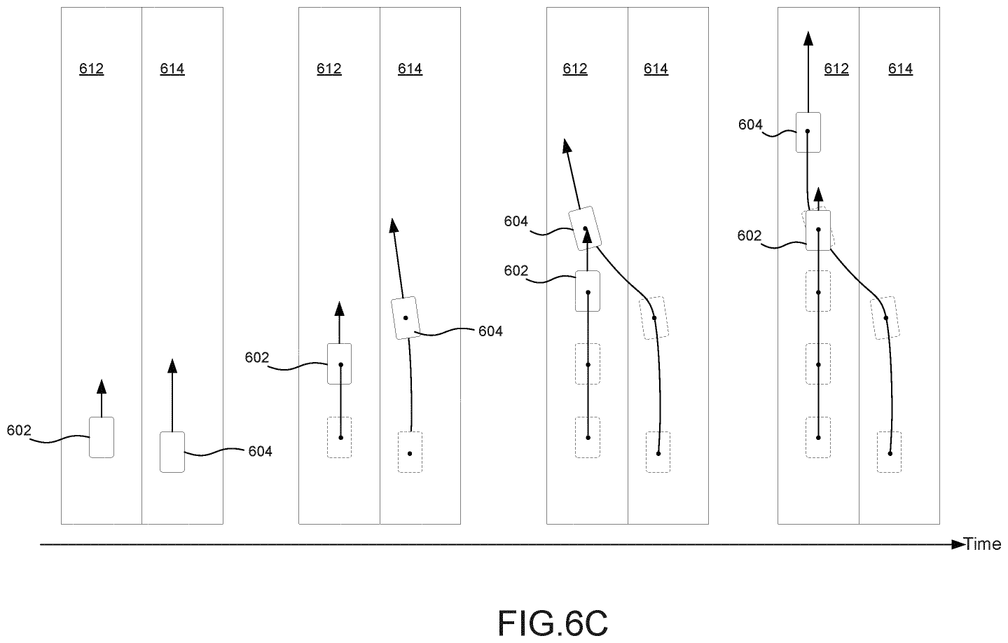

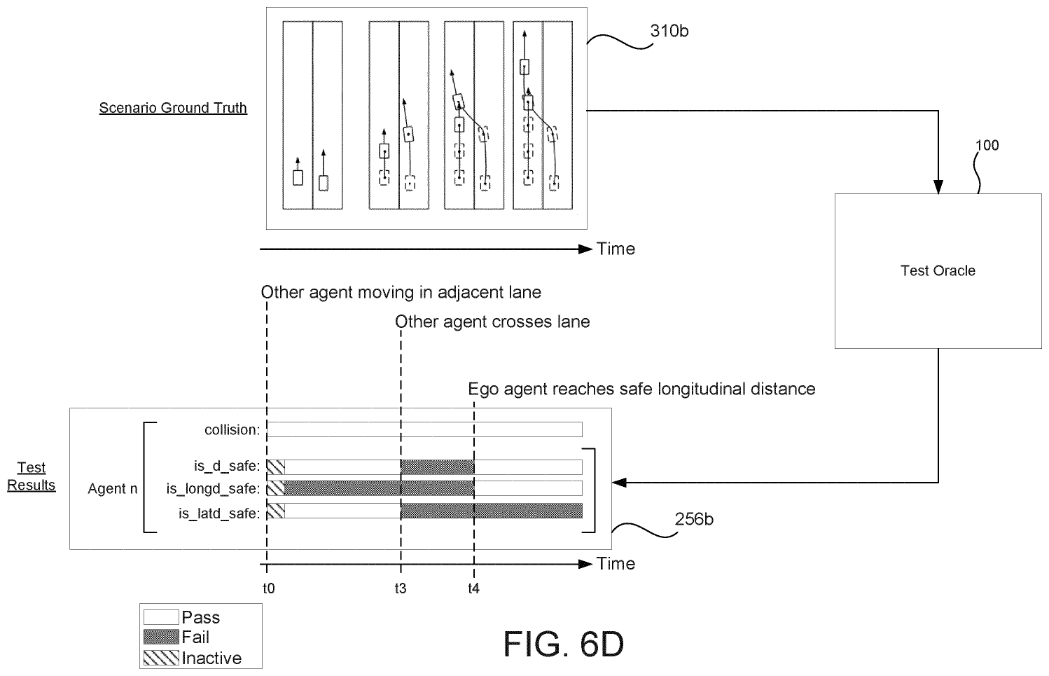

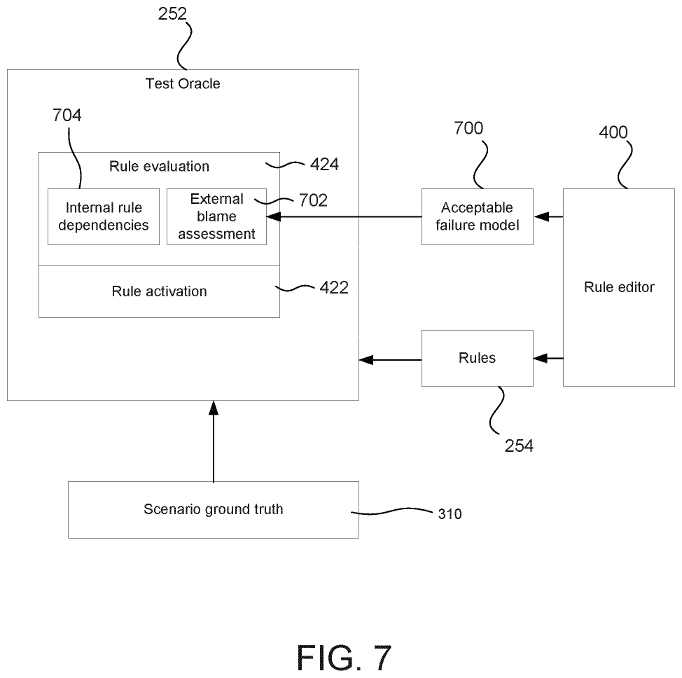

FIG. 6A depicts a first instance of a cut-in scenario in the simulator 202 that terminates in a collision event between an ego vehicle 602 and another vehicle 604. The cut-in scenario is characterized as a multi-lane driving scenario, in which the ego vehicle 602 is moving along a first lane 612 (the ego lane) and the other vehicle 604 is initially moving along a second, adjacent lane 604. At some point in the scenario, the other vehicle 604 moves from the adjacent lane 614 into the ego lane 612 ahead of the ego vehicle 602 (the cut-in distance). In this scenario, the ego vehicle 602 is unable to avoid colliding with the other vehicle 604. The first scenario instance terminates in response to the collision event.

FIG. 6B depicts an example of a first oracle output 256a obtained from ground truth 310a of the first scenario instance. A “no collision” rule is evaluated over the duration of the scenario between the ego vehicle 602 and the other vehicle 604. The collision event results in failure on this rule at the end of the scenario. In addition, the “safe distance” rule of FIG. 4B is evaluated. As the other vehicle 604 moves laterally closer to the ego vehicle 602, there comes a point in time (t1) when both the safe lateral distance and safe longitudinal distance thresholds are breached, resulting in failure on the safe distance rule that persists up to the collision event at time t2.

FIG. 6C depicts a second instance of the cut-in scenario. In the second instance, the cut-in event does not result in a collision, and the ego vehicle 602 is able to reach a safe distance behind the other vehicle 604 following the cut-in event.

FIG. 6D depicts an example of a second oracle output 256b obtained from ground truth 310b of the second scenario instance. In this case, the “no collision” rule is passed throughout. The safe distance rule is breached at time t3 when the lateral distance between the ego vehicle 602 and the other vehicle 604 becomes unsafe. However, at time t4, the ego vehicle 602 manages to reach a safe distance behind the other vehicle 604. Therefore, the safe distance rule is only failed between time t3 and time t4.

### Blame Assessment:

Blame or responsibility is an important concept in an interactive agent scenario. If a failure occurs in a scenario run, the question of the ego agent is at fault in a given scenario is important in determining whether or not an undesired event arose from a problem within the stack 100 under testing. In one sense, blame is an intuitive concept. However, it is a challenging concept to apply in the context of a formal safety model and rules-based performance testing more generally.

For example, in the first scenario instance of FIG. 6A, the collision event could be the responsibility of the ego agent 602 or the other agent 604 depending on the circumstances of the cut-in action by the other agent 604.

An extension of the testing framework will now be described that formalizes the concept blame and thus allows blame to be assessed objectively in a similarly rigorous and unambiguous manner.

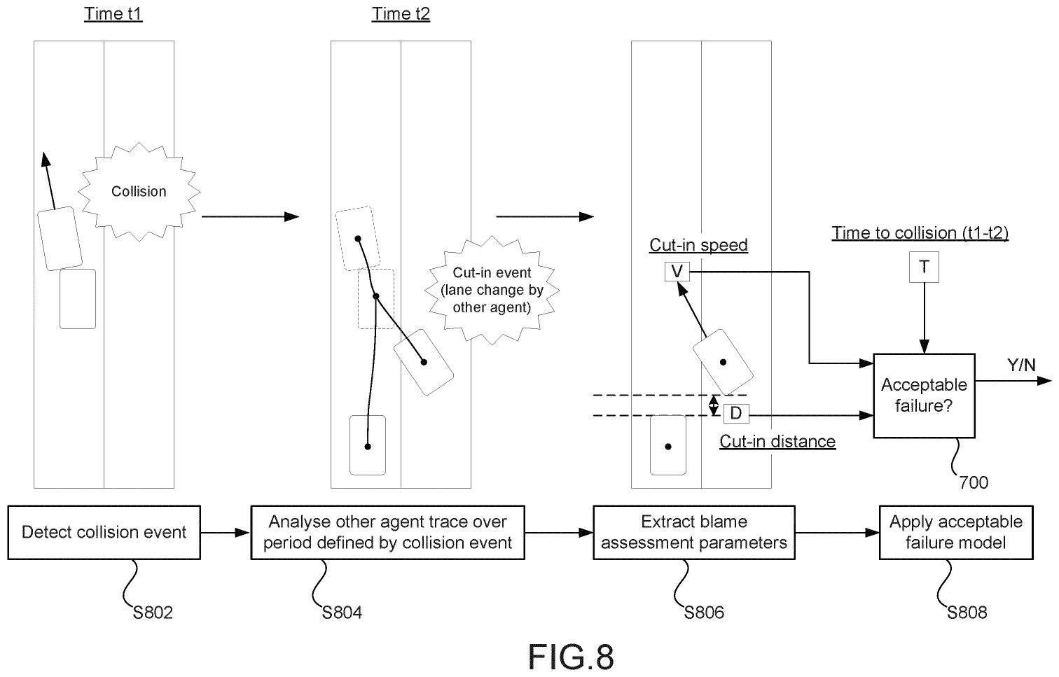

FIG. 7 shows an extension of the test oracle 252 to incorporate “external” blame assessment logic 702. When a failure occurs on a rule for a given agent pairing (the ego agent and another agent), an assessment is made as to whether the ego agent or the other agent is responsible for the failure. The following examples consider collision events, characterized as failure on a top-level “no collision” rule. However, the same principles can be applied to any type of rule, anywhere in the hierarchy of the rules that are applicable to a given scenario run. In the following description, a failure on a rule that is determined to be the responsibility of the other agent rather than the ego agent may be termed an “acceptable failure”. The notion of a formal safety model is extended to include an “acceptable failure” model—the aim being to formally distinguish between failures that the ego agent should have been able to prevent, from failures that no ego agent could reasonably be expected to prevent.

Note, the external blame assessment is distinct from any “internal” evaluation of rule interdependencies by any internal rule evaluation logic 704. For example, as described above, failure on a given comfort rule may, in some implementations, be deemed acceptable or justified in a more general sense when another rule that takes precedence over the comfort rule is activated, such as an emergency braking rule.

The external blame assessment is also distinct from the rule activation logic 422. The rule evaluation logic selectively activates rules applicable to the scenario. For example, the safe distance rule may be deactivated for any agent that is more than a certain distance behind the ego vehicle. The motivation for deactivating the safe distance rule in this situation might be that maintaining a safe distance is the responsibility of the other agent (not the ego vehicle) in this situation.

However, the external blame assessment logic 702 applies to activated rules, and operates to determine whether the ego agent or the other agent was the cause of the failure on the active rule.

To this end, an acceptable failure model 700 is defined for a given scenario and provided as a second input to the test oracle 252. The functionality of the rule editor 400 is extended for defining acceptable behaviour models. The focus of the following description, and the acceptable failure model 700, is failures on active rules that are not explained or justified by the internal hierarchy of the rules applicable to a given scenario run, and which require investigation of the behaviour of another agent in the scenario.

The described examples introduce at least three categories of result: “pass” and, in addition, two distinct categories or classes of “failure”—“acceptable failure” that is the fault of the other agent according to the acceptable failure model 700, and an “unacceptable failure” that is not the fault of the other agent according to the acceptable behaviour mode 700. Note the term “unacceptable” in this context refers specifically to the outcome against the acceptable failure model 700; it does not exclude the possibility that the rule is justified in some other sense (e.g. according to the internal rule hierarchy).

An alternative would be to encode some implicit notion of acceptable failure in a pass/fail-type rule. For example, consider a basic “no collision” rule that is failed whenever an area of the ego agent 602 intersects an area of the other agent 604, and passed otherwise. This rule could be extended to attach further conditions for failure dependent on the behaviour of the other agent 604. For example, the rule could instead be formulated as “fail whenever an area of the ego agent 602 intersects an area of the other agent 604 (collision event), unless a cut in action has been performed by the other agent less than T seconds before the collision event”. However, there are two problems with this approach. Firstly, it could result in a pass on the no collision rule, even when a collision takes place. That is a highly misleading characterization of the scenario run that could have critical implication in the context of safety testing.

An efficient two-stage implementation of acceptable behaviour is described. The rules 254 are formulated as pass/fail-type rules, and the first stage evaluates each applicable rule to compute pass/fail results at each time instant at which that rule is active, to determine a pass/fail result. The first stage is independent of the acceptable failure model 700. Second stage processing is only performed in response to a failure on the rule, in order to assess the behaviour of the other agent against the acceptable behaviour model 700 (blame analysis). This may be performed for all failures, or only certain failures—e.g. only failures on a specific rule or rule and/or failures that are not justified by the internal rule hierarchy.

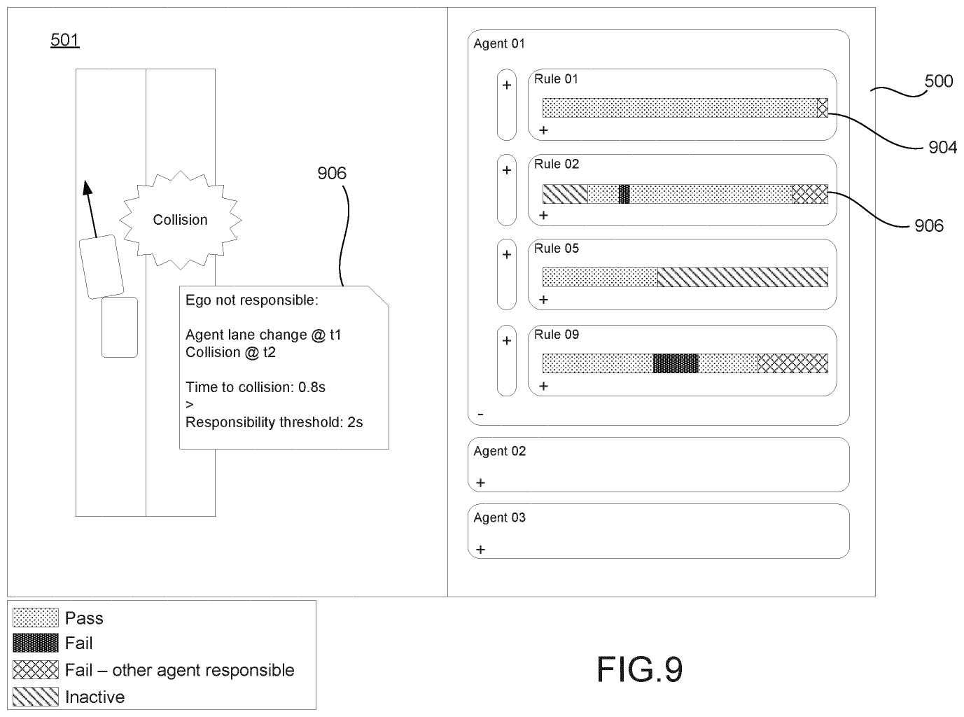

FIG. 8 shows a schematic flow chart for the second stage processing, together with a high-level visual representation of the processing performed at each step. The example of FIG. 8 considers a blame analysis instigated by the collision event in the scenario run of FIG. 6a, but the description applies more generally to other types of rule failure.

At step S802 a collision event is detected in a given scenario run, as a failure on some top-level “no collision” rule evaluated pairwise between the ego agent 602 and the other agent 604. The collision event is determined to occur at time t2 of the scenario run.

At step S804, in response to the detected collision event, the trace of the other agent 604 is analysed over a period of time before and/or after a timing of the collision event. In the present example, the trace of the other agent 604 is used to locate an earlier cut-in event at time t1 occurring within the time period under consideration. The cut-in event is defined at the point at which the other agent 604 crossed from the adjacent lane 614 into the ego lane 612.

A partial trace 704 of the other agent 604 between time t1 and time t2 is shown and forms part of the ground truth of the scenario run.

At step 806, the partial agent trace 704 is used to extract one or more blame assessment parameters. The blame assessment parameters are the parameter(s) required to evaluate the acceptable failure model 700 applicable to the scenario.

At step S808, the acceptable failure model 700 is applied to the extracted blame assessment parameters. That is to say, a rules-based evaluation of the blame assessment parameter(s) is performed according to the rule(s) of the acceptable failure model 700, in order to class the failure as acceptable or unacceptable in the above sense.

In the depicted cut-in scenario, one such parameter could be time-to-collision, t=t2−t1, i.e. the time interval between the cut in event and the rule failure. For example, a simple blame assessment rule could be defined as follows:
“a collision is acceptable in a cut-in scenario if the other agent crosses the lane boundary of the ego lane with a time to collision of less than T”
where T is some predefined threshold (e.g. 2 seconds).

Other examples of potentially important parameters in a cut-in scenario are the speed, v, of the other agent 604 at the time t1 of the cut-in event, and cut-in distance, d, between the ego agent 602 and the other agent 604.

In the cut-in example, an overriding requirement of this particular blame assessment rule is that a cut-in event has occurred before the rule failure under investigation. This requirement could be evaluated by checking for the existence of a cut in event in the time period between time t1−T and time t1. In this case, a requirement for ascribing blame to the other agent is the existence of a cut-in event in that period.

Cut-in distance, d, is an example of a blame assessment parameter that also requires the cut-in event at time t1 to be identified. A partial trace 702 of the ego agent 602 is depicted in the visual representation of step S804, and the cut-in distance d is defined in this example as the lateral distance between a front bumper of the ego agent 602 and a rear bumper of the other agent 604.

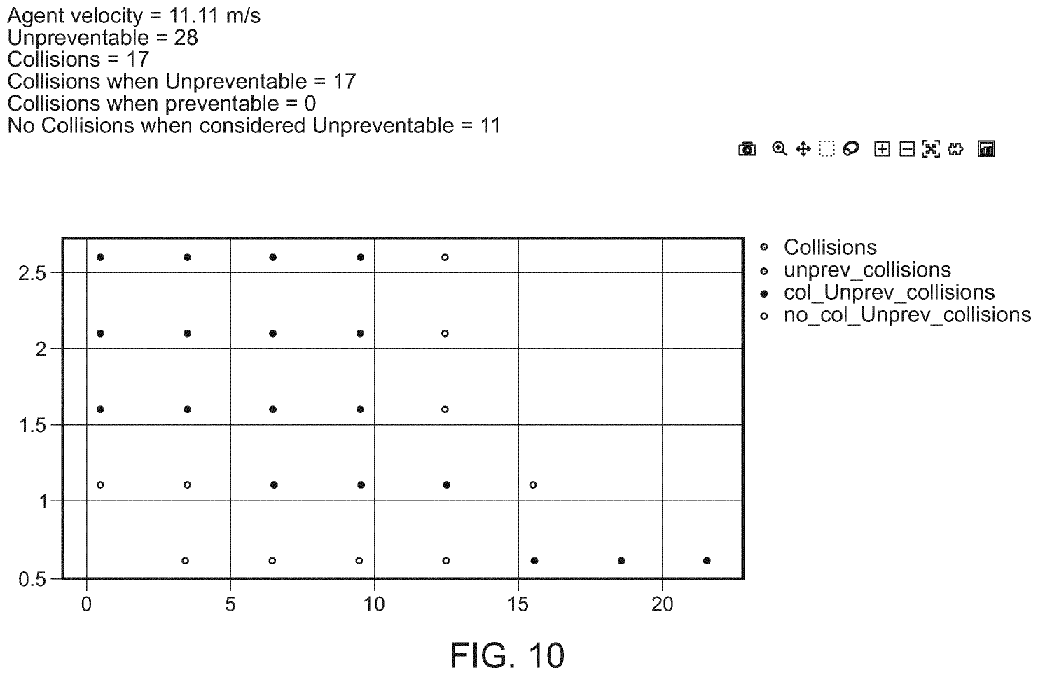

FIG. 9 shows an example of an extended GUI, to incorporate the results of a blame assessment analysis. Different colours (denoted by shading) are used to represent pass, acceptable failure and unacceptable failure. Over the duration of the depicted run, intervals of failure can be seen in the timelines for “Rule 01” and “Rule 02”. For example, Rule 01 could be the “no collision” rule and Rule 02 could be the “safe distance” rule. A blame analysis has been performed in relation to each interval of failure. First and second failure intervals 904 and 906, on Rule 01 and Rule 02 respectively, occur towards the end of the scenario when the cut-in and subsequent collision event occur. Those intervals 904, 906 have been visually marked as acceptable, whereas a third interval of failure 908 has been visually marked as unacceptable.

The visual representation 501 of the scenario run relates to the time t1 of the collision event. Details 906 of the blame analysis pertaining to time t1 are also displayed. For example, the details 906 may be displayed in response to the user selecting the corresponding interval 904 of the timeline of Rule 01 and/or navigating to time t1 in the visualization 501. Regarding the latter, a suitable GUI element, such as a slider 912 may be proved for this purpose.

FIG. 9A shows the visual representation 501 at an earlier time, with details 912 of the unacceptable failure interval 908 on Rule 02 obtained in the blame assessment analysis. This failure occurs before the cut-in by the other agent 604, and is therefore not explained by it. According to the acceptable behaviour model 700, the fault lies with the ego agent 602, and requires further investigation of the stack 100 under testing.

In a lane driving context, one possible basis for the acceptable failure model 700 may be found in “Proposal for a new UN Regulation on uniform provisions concerning the approval of vehicles with regards to Automated Lane Keeping System” at https://undocs.org/ECE/TRANS[WP.29)/2020/81, the contents of which is incorporated herein by reference in its entirety. The aforementioned reference considers an attentive human driver performance model applied to cut-in, cut-out and deceleration scenarios (referred to as the ‘ALKS unavoidable collision model’ herein). For a cut-in scenario, a normal “wandering” distance for an agent within a lane is defined, and a perceived boundary for cut-in occurs when the other vehicle exceeds the normal lateral wandering distance (possibly prior to actual lane change). The model is applied to the following set of parameters: Ve0 (ego velocity), Ve0-Vo0 (relative velocity of the other vehicle performing the cut in), dy0 (lateral distance between ego and other vehicle), dx0 (longitudinal distance between the ego and other vehicle) and Vy (lateral velocity of other vehicle), as measured at the start of the cut-in (when the perceived cut-in boundary is exceeded). By applying the ALKS unavoidable collision model to a given combination of these parameters, it can be determined whether or not collision is avoidable under the conditions represented by the parameter combination.

A variant of the above implementation applies the acceptable failure model 700 to each scenario, in order to determine whether failure on a rule or rule combination would be acceptable, irrespective of whether such a failure event actually occurs. To an AV developer, this approach has the benefit of revealing scenarios in which failure would be acceptable, according to the acceptable failure model 700, but the stack 100 does not actually fail. In those circumstances, the stack 100 has outperformed the acceptable failure model 700 (e.g. outperforming a reasonable human driving baseline).

The following examples refer to the ALKS unacceptable collision model, but the description applies equally to other forms of acceptable failure model 700 and/or other types of failure event (other than collisions).

A user creates an abstract scenario, such as a cut-in, with certain specified parameters (such as starting position for the other agent, a starting velocity etc.) At execution time, to sample the scenario space, the user specifies ranges for certain parameters, such as dx0 (distance ahead of ego that the agent will cut in), and Vy the lateral velocity. The scenario instances are run with different combinations of those parameters, and the test oracle 252 assesses the resulting traces in each run.

In addition to the performance evaluation rule(s), at each step of the run, the test oracle 252 determined whether an acceptable failure condition is satisfied. Taking the ALKS unavoidable collision model as an example, an acceptable failure condition is determined to be satisfied if and when (i) the other vehicle crosses the perceived cut-in boundary (the start of the cut-in action) and (ii) the relevant parameters of the cut-in action at that point in time—e.g. the parameters (Ve0, Ve0−Vo0, dy0, dx0, Vy), or some subset thereof—are such that a collision event would be acceptable according to the ALKS model. Satisfaction of the acceptable failure condition implies that failure on a given rule or rule combination by the ego agent (e.g. failure on a ‘no collision’ rule) would be an acceptable outcome according to the acceptable behaviour model 700, irrespective of whether such a failure event actually occurs. This, in turn, allows each scenario to be classified in one of four ways:
1. The acceptable failure condition has not been satisfied, and no failure event has occurred (the ego agent is expected to avoid failure, and has done so);
2. The acceptable failure condition has not been satisfied, but a failure event has occurred (an unacceptable failure by the ego agent, indicating an issue with the stack 100 under testing);
3. The acceptable failure condition has been satisfied, and a failure event has occurred (the ego agent has not avoided failure, but was not expected to do so);
4. The acceptable failure condition has been satisfied, but no failure event has occurred (the ego agent was not expected to avoid failure, but has nevertheless managed to do so; the stack 100 has outperformed the acceptable failure model 700).

A distinction is drawn between the parameterization 201b of the scenario that is inputted to the simulator 202 and the blame assessment parameters to which the acceptable failure model 700. The latter are extracted from the traces to account for the actual behaviour of the agents in the scenario run: depending on how the scenario is configured, the actual behaviour may deviate, as the outcome of the scenario is determined by the decisions within the stack 100 and any autonomous agent decision logic 210 (e.g. in some cases, it may be that no cut in actually occurs in a cut in scenario, and the described techniques are robust to such an outcome, among others).

A scenario run may nevertheless be characterized within the system by its parameterization 201b, and that parameterization 201b (corresponding to a point in the scenario space) may be classified into one of the above four categories. In order to perform that classification the scenario is run with that parameter combination, and the above processing steps are applied to the resulting traces 212a, 212b.

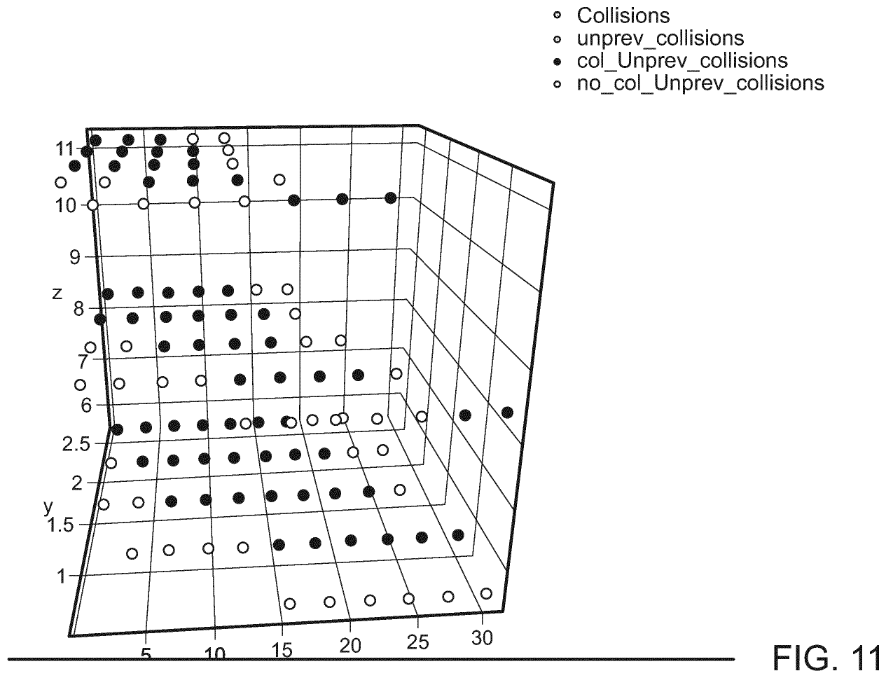

FIG. 10 shows an example of acceptable failure results summarized over multiple runs. FIG. 10 shows a region of the scenario space, and each point corresponds to a particular parameterization 201b of a given abstract scenario. The points are classified according to the outcome of the corresponding run.

FIG. 11 shows similar results for a scenario space of at least three dimensions.

Whilst the above examples consider a collision event, the techniques can be applied more generally to other types of failure event. A failure event could be a failure result on a particular rule, but could also be a particular combination of failure results on a single rule or multiple rules. Having identified a failure event, a blame assessment analysis can be instigated and conveyed in a similar manner.

Whilst the above examples consider AV stack testing, the techniques can be applied to test components of other forms of mobile robot. Other mobile robots are being developed, for example for carrying freight supplies in internal and external industrial zones. Such mobile robots would have no people on board and belong to a class of mobile robot termed UAV (unmanned autonomous vehicle). Autonomous air mobile robots (drones) are also being developed.

A computer system comprises execution hardware which may be configured to execute the method/algorithmic steps disclosed herein and/or to implement a model trained using the present techniques. The term execution hardware encompasses any form/combination of hardware configured to execute the relevant method/algorithmic steps. The execution hardware may take the form of one or more processors, which may be programmable or non-programmable, or a combination of programmable and non-programmable hardware may be used. Examples of suitable programmable processors include general purpose processors based on an instruction set architecture, such as CPUs, GPUs/accelerator processors etc. Such general-purpose processors typically execute computer readable instructions held in memory coupled to or internal to the processor and carry out the relevant steps in accordance with those instructions. Other forms of programmable processors include field programmable gate arrays (FPGAs) having a circuit configuration programmable though circuit description code. Examples of non-programmable processors include application specific integrated circuits (ASICs). Code, instructions etc. may be stored as appropriate on transitory or non-transitory media (examples of the latter including solid state, magnetic and optical storage device(s) and the like). The subsystems 102-108 of the runtime stack FIG. 1 may be implemented in programmable or dedicated processor(s), or a combination of both, on-board a vehicle or in an off-board computer system in the context of testing and the like. The various components of FIG. 2, such as the simulator 202 and the test oracle 252 may be similarly implemented in programmable and/or dedicated hardware.

1. A computer-implemented method of evaluating the performance of a trajectory planner for a mobile robot in a real or simulated scenario, the method comprising:
receiving scenario ground truth of the scenario, the scenario ground truth generated using the trajectory planner to control an ego agent of the scenario responsive to at least one other agent of the scenario, and comprising an ego trace of the ego agent and an agent trace of the other agent;
evaluating the ego trace, by a test oracle, in order to assign at least one time series of test results to the ego agent, the time-series of test results pertaining to at least one performance evaluation rule;
extracting one or more predetermined blame assessment parameters based on the agent trace; and
applying one or more predetermined blame assessment rules to the blame assessment parameters, and thereby determining whether failure on the at least one performance evaluation rule is acceptable.

2. The method of claim 1, comprising the step of detecting an action by the other agent of a predetermined type, wherein the blame assessment parameters are extracted based on the detected action.

3. The method of claim 2, wherein the blame assessment parameters comprise a distance between the ego agent and the other agent at a time of the detected action.

4. The method of claim 2, wherein the blame assessment parameters comprise at least one motion parameter of the other agent at a time of the detected action.

5. The method of claim 1, wherein the one or more predetermined blame assessment rules are applied to identify one of the ego agent and the other agent as having caused a failure event in the at least one time series of test results.

6. The method of claim 2, wherein the one or more predetermined blame assessment rules are applied to identify one of the ego agent and the other agent as having caused a failure event in the at least one time series of test results; and wherein the action occurs before the failure event.

7. The method of claim 6, wherein the blame assessment parameters comprise a time interval between the detected action and the failure event.

8. The method of claim 7, wherein the one or more predetermined blame assessment parameters are extracted responsive to the failure event in the at least one timeseries of test results based on the agent trace and a timing of the failure event.

9. The method of claim 1, wherein the predetermined blame assessment rules are applied irrespective of whether any failure event occurs in the at least one time series of test results.

10. The method of claim 9, wherein the scenario is assigned a classification label denoting that:
an acceptable failure event occurred in the at least one time-series of test results,
an unacceptable failure event occurred in the at least one time-series of test results,
no failure event occurred in the at least one time-series of test results and such a failure event would not have been acceptable, or
no failure event occurred in the at least one time-series of test results and such a failure event would have been acceptable.

11. The method of claim 10, wherein the classification label is stored in association with a set of scenario parameters parameterizing the scenario.

12. The method of claim 11, comprising generating display data for generalizing a visualization of the scenario parameters and the classification label.

13. The method of claim 1, comprising the step of generating display data for displaying a rule timeline with a visual indication of whether failure on the at least one performance evaluation rule is acceptable, the rule timeline being a visual representation of the time-series.

14. The method of claim 13, wherein:
the one or more predetermined blame assessment rules are applied to identify one of the ego agent and the other agent as having caused a failure event in the at least one time series of test results; and
the failure result and the causing agent are visually identified in the rule timeline.

15. The method of claim 13, comprising the step of rendering a graphical user interface comprising the rule timeline with the visual indication.

16. The method of claim 1, comprising the step of storing the time-series of results in a test database, with an indication of whether failure on the at least one performance evaluation rule is acceptable.

17. The method of claim 16, wherein:
the one or more predetermined blame assessment rules are applied to identify one of the ego agent and the other agent as having caused a failure event in the at least one time series of test results; and
the time-series of results is stored in the test database with an indication of the causing agent.

18. The method of claim 5, wherein the predetermined blame assessment rules are applied to only a portion of the agent trace within a time period defined by the timing of the failure event.

19. A computer system comprising one or more computers configured to implement the method of evaluating the performance of a trajectory planner for a mobile robot in a real or simulated scenario, the method comprising:
receiving scenario ground truth of the scenario, the scenario ground truth generated using the trajectory planner to control an ego agent of the scenario responsive to at least one other agent of the scenario, and comprising an ego trace of the ego agent and an agent trace of the other agent:
evaluating the ego trace, by a test oracle, in order to assign at least one time series of test results to the ego agent, the time-series of test results pertaining to at least one performance evaluation rule:
extracting one or more predetermined blame assessment parameters based on the agent trace; and
applying one or more predetermined blame assessment rules to the blame assessment parameters, and thereby determining whether failure on the at least one performance evaluation rule is acceptable.

20. One or more computer programs, embodied in non-transitory media, and configured when executed by one or more computers to implement the method of evaluating the performance of a trajectory planner for a mobile robot in a real or simulated scenario, the method comprising:
receiving scenario ground truth of the scenario, the scenario ground truth generated using the trajectory planner to control an ego agent of the scenario responsive to at least one other agent of the scenario, and comprising an ego trace of the ego agent and an agent trace of the other agent:
evaluating the ego trace, by a test oracle, in order to assign at least one time series of test results to the ego agent, the time-series of test results pertaining to at least one performance evaluation rule;
extracting one or more predetermined blame assessment parameters based on the agent trace; and
applying one or more predetermined blame assessment rules to the blame assessment parameters, and thereby determining whether failure on the at least one performance evaluation rule is acceptable.
